(19) United States
(12) Patent Application Publication
(10) Pub. No.: US 2026/0353920 A1
(43) Pub. Date: Nov. 5, 2026

(54) DISPLAY DEVICE AND ELECTRONIC DEVICE COMPRISING THE SAME

(71) Applicant: Samsung Display Co., Ltd., Yongin-si (KR)

(72) Inventors: Hyun Ae PARK, Yongin-si (KR); Min Ki YANG, Yongin-si (KR); Mi Hae KIM, Yongin-si (KR); Hey Jin SHIN, Yongin-si (KR)

(21) Appl. No.: 19/353,378

(22) Filed: Oct. 8, 2025

(30) Foreign Application Priority Data
Mar. 7, 2025 (KR) 10-2025-0029495

(51) Int. Cl. H10K 59/121; G09G 3/3233; H10K 59/131

(52) U.S. Cl. CPC H10K 59/1213; G09G 3/3233; H10K 59/131; G09G 2300/0426; G09G 2300/0819; G09G 2300/0852; G09G 2300/0861; G09G 2330/02

(57) ABSTRACT

A display device and an electronic device are disclosed. According to various embodiments, a display device includes: a substrate; an active layer; a first gate metal layer on the active layer and including gate electrodes of second and fifth transistors; a third gate metal layer on the first gate metal layer and including a first gate line configured to receive a first gate signal and a second gate line configured to receive a second gate signal; and a connection metal layer on the third gate metal layer and including a first gate connection electrode electrically connected to the first gate line and a second gate connection electrode electrically connected to the second gate line. The gate electrode of the second transistor is electrically connected to the first gate connection electrode, and the gate electrode of the fifth transistor is electrically connected to the second gate connection electrode.

### CROSS-REFERENCE TO RELATED APPLICATION

This application claims priority to and the benefit of Korean Patent Application No. 10-2025-0029495, filed on Mar. 7, 2025, in the Korean Intellectual Property Office, the contents of which in its entirety are herein incorporated by reference.

### BACKGROUND

### 1. Field

Embodiments of the present disclosure relate to a display device and an electronic device including the same.

### 2. Description of the Related Art

Electroluminescence displays may be divided into inorganic light emitting displays and organic light emitting displays depending on the material of a light emitting layer. An organic light emitting display of an active matrix type includes an organic light emitting diode (hereinafter, referred to as “OLED”) that emits light by itself, and has the advantages of a relatively fast response speed, relatively high emission efficiency, relatively high brightness, and relatively large viewing angle. The organic light emitting display generally has the organic light emitting diode (OLED) formed in each pixel. The organic light emitting display may not only have a relatively fast response speed and excellent or suitable emission efficiency, brightness, and viewing angle, but also may have excellent or suitable contrast ratio and color reproducibility because the organic light emitting display may express black gradations as complete black.

### SUMMARY

Aspects of embodiments of the present disclosure are directed to securing or providing a degree of freedom in line design.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to various embodiments of the present disclosure, a display device includes: a substrate; an active layer on the substrate; a first gate metal layer on the active layer and including a gate electrode of a second transistor and a gate electrode of a fifth transistor; a third gate metal layer on the first gate metal layer and including a first gate line configured to receive a first gate signal and a second gate line configured to receive a second gate signal; and a connection metal layer on the third gate metal layer and including a first gate connection electrode electrically connected to the first gate line and a second gate connection electrode electrically connected to the second gate line. The gate electrode of the second transistor is electrically connected to the first gate connection electrode, and the gate electrode of the fifth transistor is electrically connected to the second gate connection electrode.

According to various embodiments of the present disclosure, the first gate metal layer further includes a gate electrode of a third transistor, the third gate metal layer further includes a third gate line configured to receive the second gate signal, the connection metal layer further includes a third gate connection electrode electrically connected to the third gate line, and the gate electrode of the third transistor may be electrically connected to the third gate connection electrode.

According to various embodiments of the present disclosure, the first gate metal layer further includes a gate electrode of a fourth transistor, the third gate metal layer further includes a fourth gate line configured to receive a fourth gate signal, the connection metal layer further includes a fourth gate connection electrode electrically connected to the fourth gate line, and the gate electrode of the fourth transistor may be electrically connected to the fourth gate connection electrode.

According to various embodiments of the present disclosure, the first gate metal layer further includes a gate electrode of a sixth transistor, the third gate metal layer further includes an emission control line configured to receive an emission control signal, the connection metal layer further includes an emission control connection electrode electrically connected to the emission control line, and the gate electrode of the sixth transistor may be electrically connected to the emission control connection electrode.

According to various embodiments of the present disclosure, the first gate metal layer further includes a fifth gate line configured to receive a fifth gate signal, the connection metal layer further includes a data line, the first gate line, the second gate line, and the fifth gate line extend in a first direction, and the data line may extend in a second direction intersecting the first direction.

According to various embodiments of the present disclosure, the display device may further include a second gate metal layer between the first gate metal layer and the third gate metal layer and including a second bias voltage line configured to receive a bias voltage.

According to various embodiments of the present disclosure, the active layer may include a first bias voltage line configured to receive the bias voltage.

According to various embodiments of the present disclosure, the second gate metal layer may further include a first initialization voltage line configured to receive a first initialization voltage, the connection metal layer may further include a first initialization voltage connection electrode electrically connected to the first initialization voltage line, and a first electrode of the fourth transistor may be electrically connected to the first initialization voltage connection electrode.

According to various embodiments of the present disclosure, the first gate metal layer further includes a gate electrode of a tenth transistor, and the gate electrode of the tenth transistor may be electrically connected to the second gate connection electrode.

According to various embodiments of the present disclosure, the gate electrode of the tenth transistor is physically connected to the gate electrode of the fifth transistor.

According to various embodiments of the present disclosure, the first gate metal layer further includes a gate electrode of a seventh transistor, and the gate electrode of the seventh transistor may be electrically connected to the emission control connection electrode.

According to various embodiments of the present disclosure, the gate electrode of the seventh transistor is physically connected to the gate electrode of the sixth transistor.

According to various embodiments of the present disclosure, the first gate metal layer further includes a first electrode of a second capacitor, and the second gate metal layer may further include a second electrode of the second capacitor.

According to various embodiments of the present disclosure, the second gate metal layer may further include a first electrode of a first capacitor, and the third gate metal layer may further include a second electrode of the first capacitor.

According to various embodiments of the present disclosure, the connection metal layer may further include a first capacitor connection electrode electrically connected to a first electrode of the second transistor, and the first electrode of the first capacitor may be electrically connected to the first capacitor connection electrode.

According to various embodiments of the present disclosure, an electronic device includes a processor configured to provide an image signal, a display module configured to receive the image signal from the processor and display an image, and a power module configured to supply power to the display module. The display module includes: a substrate; an active layer on the substrate; a first gate metal layer on the active layer and including a gate electrode of a second transistor and a gate electrode of a fifth transistor; a third gate metal layer on the first gate metal layer and including a first gate line configured to receive a first gate signal and a second gate line configured to receive a second gate signal; and a connection metal layer on the third gate metal layer and including a first gate connection electrode electrically connected to the first gate line and a second gate connection electrode electrically connected to the second gate line. The gate electrode of the second transistor is electrically connected to the first gate connection electrode, and the gate electrode of the fifth transistor may be electrically connected to the second gate connection electrode.

According to various embodiments of the present disclosure, the first gate metal layer further includes a gate electrode of a third transistor, the third gate metal layer further includes a third gate line configured to receive the second gate signal, the connection metal layer further includes a third gate connection electrode electrically connected to the third gate line, and the gate electrode of the third transistor may be electrically connected to the third gate connection electrode.

According to various embodiments of the present disclosure, the first gate metal layer further includes a gate electrode of a fourth transistor, the third gate metal layer further includes a fourth gate line configured to receive a fourth gate signal, the connection metal layer further includes a fourth gate connection electrode electrically connected to the fourth gate line, and the gate electrode of the fourth transistor may be electrically connected to the fourth gate connection electrode.

According to various embodiments of the present disclosure, the first gate metal layer further includes a gate electrode of a sixth transistor, the third gate metal layer further includes an emission control line configured to receive an emission control signal, the connection metal layer further includes an emission control connection electrode electrically connected to the emission control line, and the gate electrode of the sixth transistor may be electrically connected to the emission control connection electrode.

According to various embodiments of the present disclosure, the first gate metal layer further includes a fifth gate line configured to receive a fifth gate signal, the connection metal layer further includes a data line, the first gate line, the second gate line, and the fifth gate line extending in a first direction, and the data line may extend in a second direction intersecting the first direction.

According to one or more embodiments of the present specification, by utilizing the third gate metal layer arranged to extend in the first direction, the use of the connection metal layer may be reduced. As the use of the connection metal layer is reduced, an additional design area for the connection metal layer among the lines included in the pixel circuit may be made available.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a perspective view of a display device according to an embodiment of the present specification;

FIG. 2 is a cross-sectional view of the display device according to an embodiment of the present specification;

FIG. 3 is a plan view of a display unit of the display device according to an embodiment of the present specification;

FIG. 4 is a block diagram of a display panel and a display driver according to an embodiment of the present specification;

FIG. 5 is a circuit diagram of one pixel of the display device according to an embodiment of the present specification;

FIG. 6 is a circuit diagram of one pixel of a display device according to another embodiment of the present specification;

FIG. 7 is a plan view of lines included in one pixel circuit according to an embodiment of the present specification;

FIG. 8 is a plan view of an active layer included in one pixel circuit according to an embodiment of the present specification;

FIG. 9 is a plan view of a first gate metal layer included in one pixel circuit according to an embodiment of the present specification;

FIG. 10 is a plan view of a second gate metal layer included in one pixel circuit according to an embodiment of the present specification;

FIG. 11 is a plan view of a third gate metal layer included in one pixel circuit according to an embodiment of the present specification;

FIG. 12 is a plan view of a connection metal layer included in one pixel circuit according to an embodiment of the present specification;

FIG. 13 is a plan view of a path along which a reference voltage is applied in one pixel circuit according to an embodiment of the present specification;

FIG. 14 is a plan view of a path along which an initialization voltage is applied to a first sub-pixel SP1 in one pixel circuit according to an embodiment of the present specification;

FIG. 15 is a plan view of all lines included in the first sub-pixel according to an embodiment of the present specification;

FIG. 16 is a plan view of an active layer, a second gate metal layer, and a connection metal layer included in the first sub-pixel according to an embodiment of the present specification;

FIG. 17 is a plan view of a third gate metal layer and a connection metal layer included in the first sub-pixel according to an embodiment of the present specification;

FIG. 18 is a plan view of a connection metal layer and a first gate metal layer included in the first sub-pixel according to an embodiment of the present specification;

FIG. 19 is a plan view of a first gate metal layer and an active layer included in the first sub-pixel according to an embodiment of the present specification;

FIG. 20 is a plan view of an active layer and a connection metal layer included in the first sub-pixel according to an embodiment of the present specification;

FIG. 21 is a cross-sectional view of a section taken along line I-I′ of FIGS. 15 to 20;

FIG. 22 is a cross-sectional view of a section taken along line II-II′ of FIGS. 15 to 20;

FIG. 23 is a cross-sectional view of a section taken along line III-III′ of FIGS. 15 to 20;

FIG. 24 is a cross-sectional view of a section taken along line IV-IV′ of FIGS. 15 to 20;

FIG. 25 is a cross-sectional view of a section taken along line V-V′ of FIGS. 15 to 20;

FIG. 26 is a cross-sectional view of a section taken along line VI-VI′ of FIGS. 15 to 20;

FIG. 27 is a cross-sectional view of a section taken along line VII-VII′ of FIGS. 15 to 20;

FIG. 28 is a block diagram of an electronic display device according to an embodiment of the present specification; and

FIG. 29 illustrates schematic diagrams of electronic devices according to various embodiments of the present specification.

### DETAILED DESCRIPTION

The advantages and features of the embodiments disclosed herein, and methods of achieving them, will become apparent upon reference to the embodiments described in detail with accompanying drawings. However, the invention according to the present disclosure is not limited to the embodiments disclosed herein, but will be embodied in many different forms, and these embodiments are provided merely to make the disclosure complete and to fully inform one of ordinary skill in the art to which the invention according to the present disclosure belongs, and the invention according to the present disclosure is defined by the scope of the claims.

References to an element or layer as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

Throughout this specification, like reference numerals refer to like components. The shapes, sizes, proportions, angles, numbers, etc. disclosed in the drawings to illustrate embodiments are exemplary and are not intended to be limiting to those shown herein. In addition, in the figures, dimensions of the various elements, layers, etc. may be exaggerated for clarity of illustration.

As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Although first, second, and the like are used to describe various components, the components are not limited by these terms. Thus, a first component referred to herein may also be a second component within the technical idea of the present invention.

Each of the features of the various embodiments disclosed herein may be combined or combinable with each other, in part or in whole, and may be technically interlocked and operated in a variety of ways, and each embodiment may be practiced independently of or in conjunction with one another.

Specific embodiments will be described below with reference to the accompanying drawings. Configurations that function substantially the same between embodiments are given the same drawing designation and repeated description is omitted.

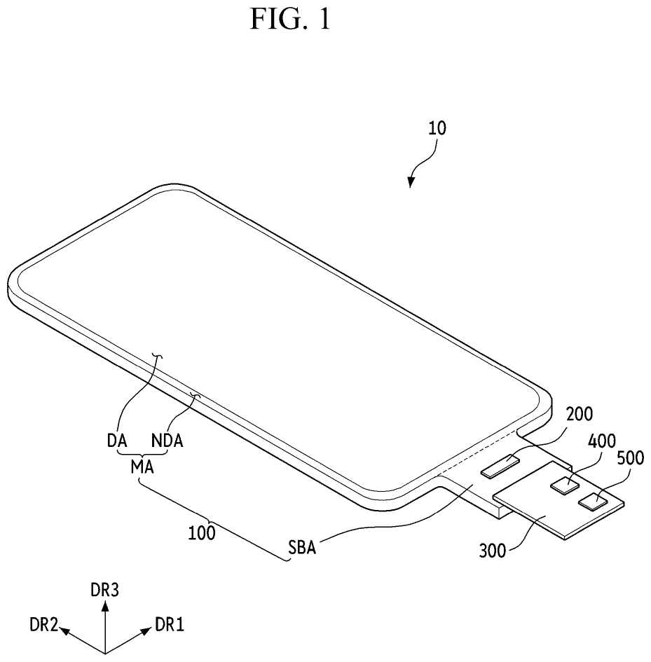

FIG. 1 is a perspective view of a display device according to an embodiment of the present specification.

Referring to FIG. 1, a display device 10 may be applied to portable electronic devices such as a mobile phone, a smartphone, a tablet personal computer (PC), a mobile communication terminal, an electronic notebook, an electronic book, a portable multimedia player (PMP), navigation, and an ultra mobile PC (UMPC). For example, the display device 10 may be applied to a display unit of a television, a laptop computer, a monitor, a billboard, or the Internet of Things (IoT). As another example, the display device 10 may be applied to a wearable device such as a smart watch, a watch phone, a glasses-type display, and a head mounted display (HMD).

The display device 10 may be formed in a planar shape similar to a quadrangle. For example, the display device 10 may have a planar shape similar to a quadrangle having short sides in a first direction DR1 and long sides in a second direction DR2. A corner where the short side in the first direction DR1 and the long side in the second direction DR2 meet may be rounded to have a curvature or may be formed at a right angle. The planar shape of the display device 10 is not limited to the quadrangle, and may be formed similarly to other polygons, circles, or ovals.

The display device 10 may include a display panel 100, a display driver 200, a circuit board 300, a touch driver 400, and a power supply unit 500.

The display panel 100 may include a main area MA and a sub-area SBA.

The main area MA may include a display area DA including pixels displaying an image, and a non-display area NDA arranged around the display area DA. The display area DA may emit light from a plurality of light emitting areas or a plurality of opening areas. For example, the display panel 100 may include a pixel circuit including switching elements, a pixel defining film defining the light emitting areas or the opening areas, and a self-light emitting element.

For example, the self-light emitting element may include at least one of an organic light emitting diode (LED) including an organic light emitting layer, a quantum dot LED including a quantum dot light emitting layer, an inorganic LED including an inorganic semiconductor, and a micro LED, but is not limited thereto.

The non-display area NDA may be an area outside the display area DA. The non-display area NDA may be defined as an edge area of the main area MA of the display panel 100. The non-display area NDA may include a gate driver (not illustrated) supplying gate signals to gate lines, and fan-out lines (not illustrated) connecting the display driver 200 and the display area DA.

The sub-area SBA may extend from one side of the main area MA. The sub-area SBA may include a flexible material that may be bent, folded, rolled, or the like. For example, when the sub-area SBA is bent, the sub-area SBA may overlap the main area MA in a thickness direction (e.g., a third direction DR3). The sub-area SBA may include the display driver 200 and a pad portion connected to the circuit board 300. In some embodiments, the sub-area SBA may be omitted, and the display driver 200 and the pad portion may be arranged in the non-display area NDA.

The display driver 200 may output signals and voltages for driving the display panel 100. The display driver 200 may supply data voltages to data lines. The display driver 200 may supply a power voltage to a power line and may supply a gate control signal to a gate driver. The display driver 200 may be formed as an integrated circuit (IC) and mounted on the display panel 100 by a chip on glass (COG) method, a chip on plastic (COP) method, or an ultrasonic bonding method. For example, the display driver 200 may be arranged in the sub-area SBA, and may overlap the main area MA in the thickness direction (the third direction DR3) by bending of the sub-area SBA. As another example, the display driver 200 may be mounted on the circuit board 300.

The circuit board 300 may be attached onto the pad portion of the display panel 100 using an anisotropic conductive film (ACF). Lead lines of the circuit board 300 may be electrically connected to the pad portion of the display panel 100. The circuit board 300 may be a flexible film such as a flexible printed circuit board, a printed circuit board, or a chip on film.

The touch driver 400 may be mounted on the circuit board 300. The touch driver 400 may be electrically connected to a touch sensing unit of the display panel 100. The touch driver 400 may supply a touch driving signal to a plurality of touch electrodes of the touch sensing unit, and may sense an amount of change in capacitance between the plurality of touch electrodes. For example, the touch driving signal may be a pulse signal having a set or predetermined frequency. The touch driver 400 may calculate whether an input is made and input coordinates based on the amount of change in capacitance between the plurality of touch electrodes. The touch driver 400 may be formed as an integrated circuit (IC).

The power supply unit 500 may be arranged on the circuit board 300, and may supply a power voltage to the display driver 200 and the display panel 100. The power supply unit 500 may generate a driving voltage to supply the driving voltage to a driving voltage line VDL, generate initialization voltages (e.g., a first initialization voltage and a second initialization voltage) to supply the initialization voltages to initialization voltage lines (e.g., a first initialization voltage line VIL1 and a second initialization voltage line VIL2), and generate a common voltage to supply the common voltage to a common electrode common to light emitting elements of a plurality of pixels. For example, the driving voltage may be a high potential voltage for driving the light emitting element, and the common voltage may be a low potential voltage for driving the light emitting element.

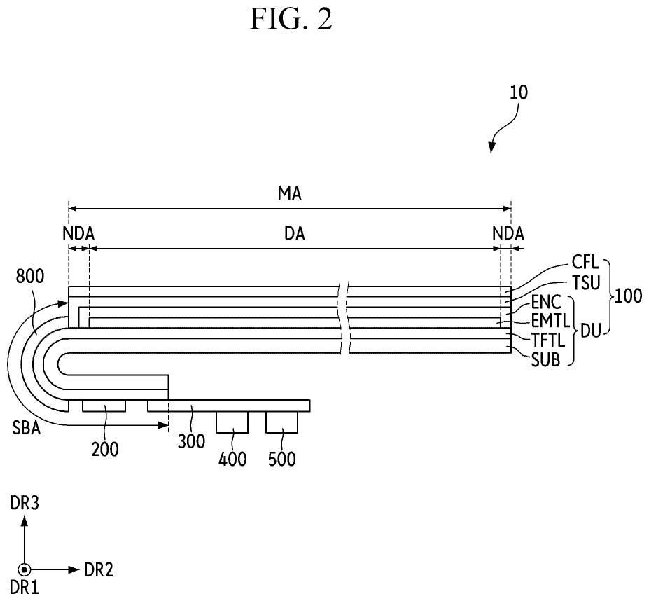

FIG. 2 is a cross-sectional view of the display device according to an embodiment of the present specification.

Referring to FIG. 2, the display panel 100 may include a display unit DU, a touch sensing unit TSU, and a color filter layer CFL. The display unit DU may include a substrate SUB, a thin film transistor layer TFTL, a light emitting element layer EMTL, and an encapsulation layer ENC.

The substrate SUB may be a base substrate or a base member. The substrate SUB may be a flexible substrate that may be bent, folded, rolled, or the like. For example, the substrate SUB may include a polymer resin such as polyimide PI, but is not limited thereto. As another example, the substrate SUB may include a glass material or a metal material.

The thin film transistor layer TFTL may be arranged on the substrate SUB. The thin film transistor layer TFTL may include a plurality of thin film transistors constituting a pixel circuit of pixels. The thin film transistor layer TFTL may further include gate lines, data lines, power lines, gate control lines, fan-out lines connecting the display driver 200 and the data lines, and lead lines connecting the display driver 200 and the pad portion. Each of the thin film transistors may include a semiconductor area, a source electrode, a drain electrode, and a gate electrode. For example, when the gate driver is formed on one side of the non-display area NDA of the display panel 100, the gate driver may include the thin film transistors.

The thin film transistor layer TFTL may be arranged in the display area DA, the non-display area NDA, and the sub-area SBA. The thin film transistors, the gate lines, the data lines, and the power lines of each of the pixels of the thin film transistor layer TFTL may be arranged in the display area DA. The gate control lines and the fan-out lines of the thin film transistor layer TFTL may be arranged in the non-display area NDA. The lead lines of the thin film transistor layer TFTL may be arranged in the sub-area SBA.

The light emitting element layer EMTL may be arranged on the thin film transistor layer TFTL. The light emitting element layer EMTL may include a plurality of light emitting elements in which a pixel electrode, a light emitting layer, and a common electrode are stacked (e.g., sequentially stacked) to emit light, and a pixel defining film defining pixels. The plurality of light emitting elements of the light emitting element layer EMTL may be arranged in the display area DA.

For example, the light emitting layer may be an organic light emitting layer including an organic material. The light emitting layer may include a hole transporting layer, an organic light emitting layer, and an electron transporting layer. When the pixel electrode receives a set or predetermined voltage through the thin film transistor of the thin film transistor layer TFTL and the common electrode receives a cathode voltage, holes and electrons may move to the organic light emitting layer through the hole transporting layer and the electron transporting layer, respectively, and may be bonded to each other in the organic light emitting layer to emit light. For example, the pixel electrode may be an anode electrode and the common electrode may be a cathode electrode, but the present specification is not limited thereto.

As another example, the plurality of light emitting elements may include a quantum dot light emitting diode including a quantum dot light emitting layer, an inorganic light emitting diode including an inorganic semiconductor, or a micro light emitting diode.

The encapsulation layer ENC may cover an upper surface and side surfaces of the light emitting element layer EMTL, and may protect the light emitting element layer EMTL. The encapsulation layer ENC may include at least one inorganic film and at least one organic film for encapsulating the light emitting element layer EMTL.

The touch sensing unit TSU may be arranged on the encapsulation layer ENC. The touch sensing unit TSU may include a plurality of touch electrodes for sensing a user's touch in a capacitance method, and touch lines connecting the plurality of touch electrodes and the touch driver 400. For example, the touch sensing unit TSU may sense the user's touch in a mutual capacitance method or a self-capacitance method.

As another example, the touch sensing unit TSU may be arranged on a separate substrate arranged on the display unit DU. In this case, the substrate supporting the touch sensing unit TSU may be a base member that encapsulates the display unit DU.

The plurality of touch electrodes of the touch sensing unit TSU may be arranged in a touch sensor area overlapping the display area DA. The touch lines of the touch sensing unit TSU may be arranged in a touch peripheral area overlapping the non-display area NDA.

The color filter layer CFL may be arranged on the touch sensing unit TSU. The color filter layer CFL may include a plurality of color filters corresponding to each of the plurality of light emitting areas. Each of the color filters may selectively transmit light of a specific wavelength and block or absorb light of a different wavelength. The color filter layer CFL may absorb a portion of light introduced from the outside of the display device 10 to reduce reflected light caused by external light. Therefore, the color filter layer CFL may prevent color distortion caused by reflection of external light.

As the color filter layer CFL is arranged (e.g., directly arranged) on the touch sensing unit TSU, the display device 10 may not require a separate substrate for the color filter layer CFL. Therefore, a thickness of the display device 10 may be relatively reduced.

The sub-area SBA of the display panel 100 may extend from one side of the main area MA. The sub-area SBA may include a flexible material that may be bent, folded, rolled, or the like. For example, when the sub-area SBA is bent, the sub-area SBA may overlap the main area MA in the thickness direction (the third direction DR3). The sub-area SBA may include a pad portion electrically connected to the display driver 200 and the circuit board 300.

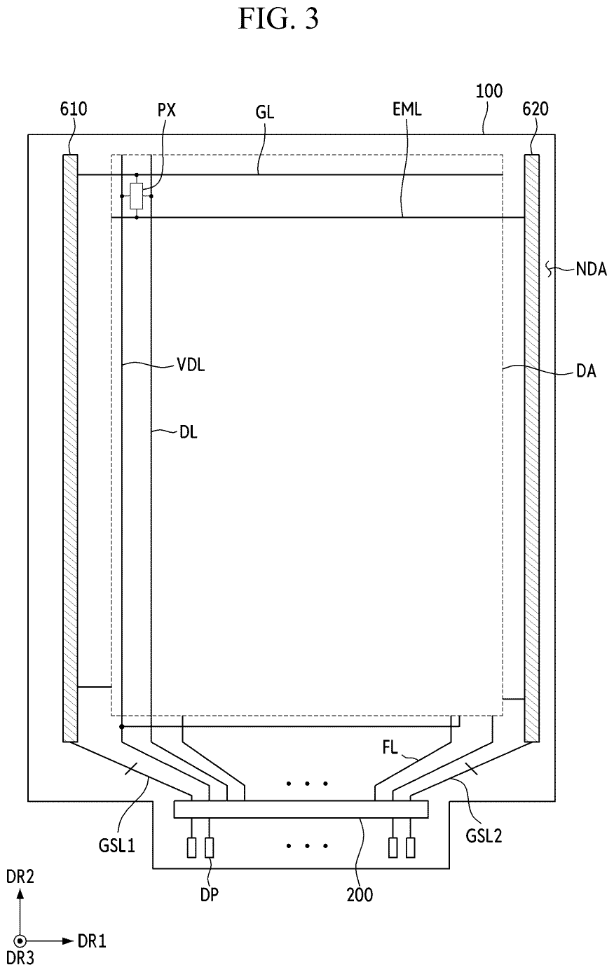

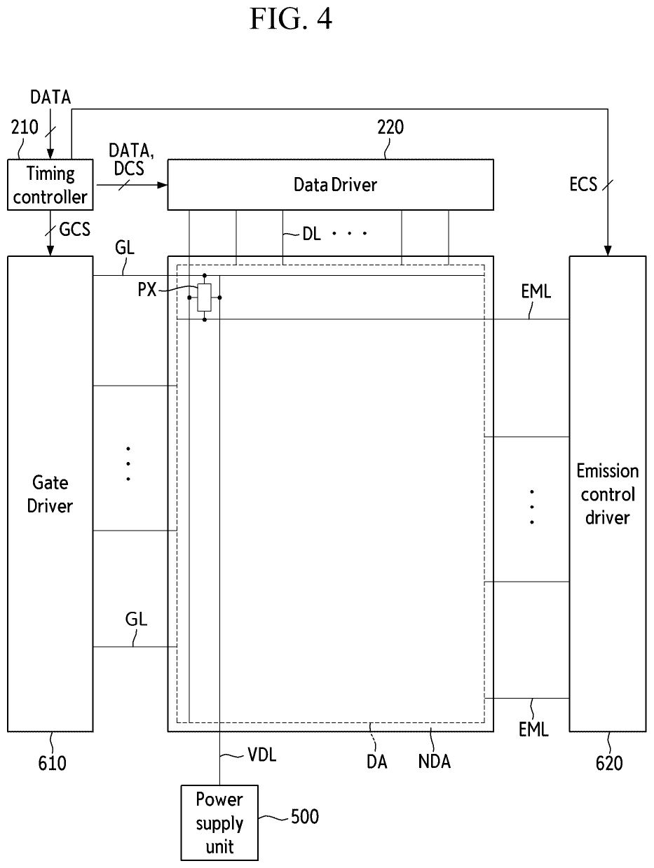

FIG. 3 is a plan view of a display unit of the display device according to an embodiment of the present specification. FIG. 4 is a block diagram of a display panel and a display driver according to an embodiment of the present specification.

Referring to FIGS. 3 and 4, the display panel 100 may include a display area DA and a non-display area NDA.

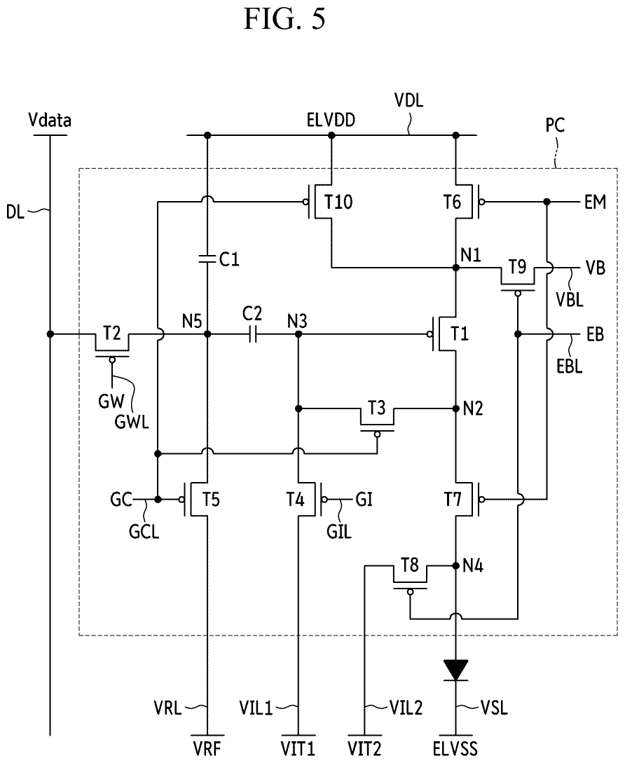

The display area DA may include a plurality of pixels PX, a plurality of driving voltage lines VDL connected to the plurality of pixels PX, a plurality of gate lines GL of a plurality of common voltage lines (VSL in FIG. 5), a plurality of emission control lines EML, and a plurality of data lines DL.

Each of the plurality of pixels PX may be connected to the gate line GL, the data line DL, the emission control line EML, the driving voltage line VDL, and the common voltage line VSL. Each of the plurality of pixels PX may include at least one transistor, a light emitting element, and a capacitor.

The gate lines GL may extend in the first direction DR1 and may be spaced apart from each other in the second direction DR2 intersecting the first direction DR1. The gate lines GL may be arranged along the second direction DR2. The gate lines GL may supply (e.g., sequentially supply) gate signals to the plurality of pixels PX.

The emission control lines EML may each extend in the first direction DR1 and may be spaced apart from each other in the second direction DR2. The emission control lines EML may be arranged along the second direction DR2. The emission control lines EML may supply (e.g., sequentially supply) an emission control signal to the plurality of pixels PX.

The data lines DL may extend in the second direction DR2 and may be spaced apart from each other in the first direction DR1. The data lines DL may be arranged along the first direction DR1. The data lines DL may supply data voltages to the plurality of pixels PX. The data voltage may determine luminance of each of the plurality of pixels PX.

The driving voltage lines VDL may each extend in the second direction DR2 and may be spaced apart from each other in the first direction DR1. The driving voltage lines VDL may be arranged along the first direction DR1. The driving voltage lines VDL may supply a first driving voltage to the plurality of pixels PX. The first driving voltage may be a high potential voltage for driving the light emitting elements of the pixels PX.

The non-display area NDA may surround the display area DA. The non-display area NDA may include a gate driver 610, an emission control driver 620, fan-out lines FL, a first gate control line GSL1, and a second gate control line GSL2.

The fan-out lines FL may extend from the display driver 200 to the display area DA. The fan-out lines FL may supply the data voltage received from the display driver 200 to the plurality of data lines DL.

The first gate control line GSL1 may extend from the display driver 200 to the gate driver 610. The first gate control line GSL1 may supply the gate control signal GCS received from the display driver 200 to the gate driver 610.

The second gate control line GSL2 may extend from the display driver 200 to the emission control driver 620. The second gate control line GSL2 may supply an emission control signal ECS received from the display driver 200 to the emission control driver 620.

The sub-area SBA may extend from one side of the non-display area NDA. The sub-area SBA may include the display driver 200 and the pad portion DP. The pad portion DP may be arranged closer to an edge of one side of the sub-area SBA than the display driver 200. The pad portion DP may be electrically connected to the circuit board 300 through an anisotropic conductive film ACF.

The display driver 200 may include a timing controller 210 and a data driver 220.

The timing controller 210 may receive digital video data DATA and timing signals from the circuit board 300. Based on the timing signals, the timing controller 210 may control an operation timing of the data driver 220 by generating a data control signal DCS, control an operation timing of the gate driver 610 by generating a gate control signal GCS, and control an operation timing of the emission control driver 620 by generating the emission control signal ECS. The timing controller 210 may supply the gate control signal GCS to the gate driver 610 through the first gate control line GSL1. The timing controller 210 may supply the emission control signal ECS to the emission control driver 620 through the second gate control line GSL2. The timing controller 210 may supply the digital video data DATA and the data control signal DCS to the data driver 220.

The data driver 220 may convert the digital video data DATA into analog data voltages and supply the analog data voltages to the data lines DL through the fan-out lines FL. The gate signals of the gate driver 610 may select the pixels PX to which the data voltage is supplied, and the selected pixels PX may receive the data voltage through the data lines DL.

The power supply unit 500 may be arranged on the circuit board 300, and may supply a power voltage to the display driver 200 and the display panel 100. The power supply unit 500 may generate a driving voltage to supply the driving voltage to the driving voltage line VDL, generate an initialization voltage to supply the initialization voltage to an initialization voltage line, and generate a common voltage to supply the common voltage to the common electrode common to the light emitting elements of the plurality of pixels.

The gate driver 610 may be arranged outside of one side of the display area DA or on one side of the non-display area NDA, and the emission control driver 620 may be arranged outside of the other side of the display area DA or on the other side of the non-display area NDA, but the present specification is not limited thereto. As another example, the gate driver 610 and the emission control driver 620 may be arranged on either one side or the other side of the non-display area NDA.

The gate driver 610 may include a plurality of transistors that generate gate signals based on the gate control signal GCS. The emission control driver 620 may include a plurality of transistors that generate emission control signals based on the emission control signal ECS. For example, the transistors of the gate driver 610 and the transistors of the emission control driver 620 may be formed on the same layer as the transistors of each of the pixels PX. The gate driver 610 may supply the gate signals to the gate lines GL, and the emission control driver 620 may supply the emission control signals to the emission control lines EML.

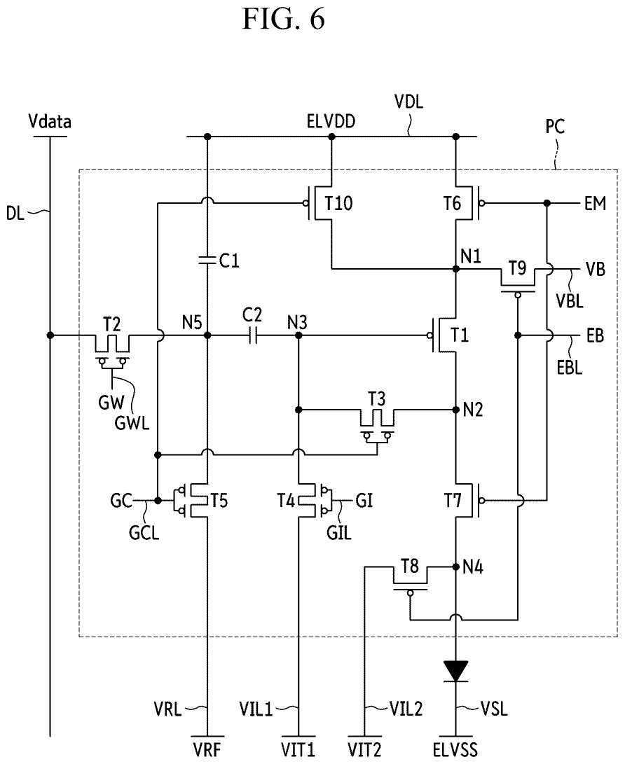

FIG. 5 is a circuit diagram of one pixel of the display device according to an embodiment of the present specification. FIG. 6 is a circuit diagram of one pixel of a display device according to another embodiment of the present specification.

In the display device according to one or more embodiments of the present specification, the pixel circuit may include a plurality of transistors. The transistor may be an oxide TFT including an oxide semiconductor or an LTPS TFT including a low temperature poly silicon (LTPS).

The transistor is a three-electrode element including a gate, a source, and a drain. The source is an electrode that supplies carriers to the transistor. In the transistor, the carriers begin to flow from the source. The drain is an electrode through which the carriers exit the transistor. In the transistor, the carriers flow from the source to the drain.

In the case of an n-channel transistor, since the carriers are electrons, a source voltage has a lower voltage than a drain voltage to allow the electrons to flow from the source to the drain. In the n-channel transistor, a direction of current flows from the drain to the source. In the case of a p-channel transistor, since the carriers are holes, the source voltage is higher than the drain voltage so that the holes may flow from the source to the drain. In the p-channel transistor, the current flows from the source to the drain because the holes flow from the source to the drain. It should be noted that the source and drain of the transistor are not fixed. For example, the source and the drain may be changed depending on the applied voltage. Therefore, the present disclosure is not limited by the source and the drain of the transistor.

In the following description, the first electrode and the second electrode of the transistor may be referred to as a source electrode and a drain electrode, respectively. For example, any transistor may include a first electrode and a second electrode. When the first electrode of any transistor is a source electrode, the second electrode of any transistor may be a drain electrode. When the second electrode of any transistor is a source electrode, the first electrode of any transistor may be a drain electrode. The source and the drain are distinguished differently depending on whether the transistor is implemented as an n-channel transistor or a p-channel transistor, and in the present specification, the terms first electrode and second electrode will be used without distinguishing whether the transistor is an n-channel transistor or a p-channel transistor.

Referring to FIGS. 5 and 6, the pixel may be connected to a first gate line GWL, second and third gate lines GCL, a fourth gate line GIL, a fifth gate line EBL, an emission control line EML, a data line DL, a driving voltage line VDL, a common voltage line VSL, a first initialization voltage line VIL1, a second initialization voltage line VIL2, a reference voltage line VRL, and a bias voltage line VBL. The second and third gate lines GCL are illustrated as a single line in the circuit diagram, but may be arranged in the pixel as a plurality of lines as illustrated in the plan view described later.

The pixel may include a pixel circuit PC and a light emitting element ED. The pixel circuit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a tenth transistor T10, a first capacitor C1, and a second capacitor C2. In the pixel circuit according to an embodiment, all of the plurality of transistors T1 to T10 may be implemented as p-channel transistors. However, this is merely one example, and the transistors according to an embodiment may also be implemented as n-channel transistors.

A first electrode of the sixth transistor T6, a second electrode of the first transistor T1, a first electrode of the ninth transistor T9, and a first electrode of the tenth transistor T10 may be connected to a first node N1.

A second electrode of the third transistor T3, a first electrode of the first transistor T1, and a second electrode of the seventh transistor T7 may be connected to a second node N2.

A first electrode of the third transistor T3, a second electrode of the second capacitor C2, and a gate electrode of the first transistor T1 may be connected to a third node N3.

A second electrode of the eighth transistor T8, a first electrode of the seventh transistor T7, and a first electrode of the light emitting element ED may be connected to a fourth node N4.

A second electrode of the second transistor T2, a first electrode of the second capacitor C2, a first electrode of the first capacitor C1, and a second electrode of the fifth transistor T5 may be connected to a fifth node N5.

A first gate signal GW, a second gate signal GC, a fourth gate signal GI, a fifth gate signal EB, an emission control signal EM, a bias voltage VB, a reference voltage VRF, a first initialization voltage VIT1, a second initialization voltage VIT2, a data voltage Vdata, a driving voltage ELVDD, and a common voltage ELVSS may be applied to the pixel circuit. For the sake of consistency of explanation and convenience of understanding, it should be noted that there is no third gate signal.

The first transistor T1 may include a gate electrode, a first electrode, and a second electrode. The first transistor T1 may control a source-drain current (hereinafter, referred to as a driving current) according to a data voltage applied to the gate electrode thereof. A driving current (e.g., Ids) flowing through a channel area of the first transistor T1 may be proportional to a square of a difference between a voltage Vgs between the second electrode and the gate electrode of the first transistor T1 and a threshold voltage Vth (Ids=k×(Vgs−Vth)²). Here, k is a proportional coefficient determined by a structure and physical characteristics of the first transistor T1, Vgs is a source-gate voltage of the first transistor T1, and Vth is a threshold voltage of the first transistor T1.

The light emitting element ED may emit light by receiving the driving current Ids. The amount of light emitted from or luminance of the light emitting element ED may be proportional to the magnitude of the driving current Ids.

The light emitting element ED may be an organic light emitting diode including a first electrode, a second electrode, and an organic light emitting layer arranged between the first electrode and the second electrode. As another example, the light emitting element ED may be an inorganic light emitting element including a first electrode, a second electrode, and an inorganic semiconductor arranged between the first electrode and the second electrode. As still another example, the light emitting element ED may be a quantum dot light emitting element including a first electrode, a second electrode, and a quantum dot light emitting layer arranged between the first electrode and the second electrode. As still another example, the light emitting element ED may be a micro light emitting diode.

The first electrode of the light emitting element ED may be electrically connected to the fourth node N4. The first electrode of the light emitting element ED may be electrically connected to the first electrode of the seventh transistor T7 and the second electrode of the eighth transistor T8 through the fourth node N4. The second electrode of the light emitting element ED may be connected to the common voltage line VSL. The second electrode of the light emitting element ED may receive a common voltage ELVSS (e.g., a low potential voltage) from the common voltage line VSL.

The second transistor T2 may be turned on by the first gate signal GW of the first gate line GWL and electrically connect the data line DL and the fifth node N5. The second transistor T2 may be turned on based on the first gate signal GW, thereby supplying the data voltage to the fifth node N5. A gate electrode of the second transistor T2 may be electrically connected to the first gate line GWL, a first electrode of the second transistor T2 may be electrically connected to the data line DL, and a second electrode of the second transistor T2 may be electrically connected to the fifth node N5.

The second transistor T2 may be configured as a dual gate transistor (see FIG. 6). For example, the second transistor T2 may include a second_a transistor and a second_b transistor connected in series between the data line DL and the fifth node N5. A gate electrode of the second_a transistor may be electrically connected to the first gate line GWL, a first electrode of the second_a transistor may be electrically connected to the data line DL, and a second electrode of the second_a transistor may be electrically connected to a first electrode of the second_b transistor. A gate electrode of the second_b transistor may be electrically connected to the first gate line GWL, a first electrode of the second_b transistor may be electrically connected to the second electrode of the second_a transistor, and a second electrode of the second_b transistor may be electrically connected to the fifth node N5.

The third transistor T3 may be turned on by the second gate signal GC of the second and third gate lines GCL and electrically connect the third node N3 and the second node N2. For example, a gate electrode of the third transistor T3 may be electrically connected to the second and third gate lines GCL, a first electrode of the third transistor T3 may be electrically connected to the third node N3, and a second electrode of the third transistor T3 may be electrically connected to the second node N2.

The third transistor T3 may be configured as a dual gate transistor (see FIG. 6). For example, the third transistor T3 may include a third_a transistor and a third_b transistor connected in series between the third node N3 and the second node N2. A gate electrode of the third_a transistor may be electrically connected to the second and third gate lines GCL, a first electrode of the third_a transistor may be electrically connected to the third node N3, and a second electrode of the third_a transistor may be electrically connected to a first electrode of the third_b transistor. A gate electrode of the third_b transistor may be electrically connected to the second and third gate lines GCL, a first electrode of the third_b transistor may be electrically connected to the second electrode of the third_a transistor, and a second electrode of the third_b transistor may be electrically connected to the second node N2.

The fourth transistor T4 may be turned on by the fourth gate signal GI of the fourth gate line GIL and electrically connect the third node N3 and the first initialization voltage line VIL1. The fourth transistor T4 may be connected in series between the third node N3 and the first initialization voltage line VIL1. For example, a gate electrode of the fourth transistor T4 may be electrically connected to the fourth gate line GIL, a second electrode of the fourth transistor T4 may be electrically connected to the third node N3, and a first electrode of the fourth transistor T4 may be electrically connected to the first initialization voltage line VIL1.

The fourth transistor T4 may be configured as a dual gate transistor (see FIG. 6). For example, the fourth transistor T4 may include a fourth_a transistor and a fourth_b transistor connected in series. A gate electrode of the fourth_a transistor may be electrically connected to the fourth gate line GIL, a first electrode of the fourth_a transistor may be electrically connected to the first initialization voltage line VIL1, and a second electrode of the fourth_a transistor may be electrically connected to a first electrode of the fourth_b transistor. A gate electrode of the fourth_b transistor may be electrically connected to the fourth gate line GIL, a first electrode of the fourth_b transistor may be electrically connected to the second electrode of the fourth_a transistor, and a second electrode of the fourth_b transistor may be electrically connected to the third node N3. The first initialization voltage line VIL1 may transmit the first initialization voltage VIT1.

The fifth transistor T5 may be turned on by the second gate signal GC of the second and third gate lines GCL and electrically connect the reference voltage line VRL and the fifth node N5. For example, a gate electrode of the fifth transistor T5 may be electrically connected to the second and third gate lines GCL, a first electrode of the fifth transistor T5 may be connected to the reference voltage line VRL, and a second electrode of the fifth transistor T5 may be electrically connected to the fifth node N5.

The fifth transistor T5 may be configured as a dual gate transistor (see FIG. 6). For example, the fifth transistor T5 may include a fifth_a transistor and a fifth_b transistor connected in series. A gate electrode of the fifth_a transistor may be electrically connected to the second and third gate lines GCL, a first electrode of the fifth_a transistor may be connected to the reference voltage line VRL, and a second electrode of the fifth_a transistor may be electrically connected to a first electrode of the fifth_b transistor. A gate electrode of the fifth_b transistor may be electrically connected to the second and third gate lines GCL, a first electrode of the fifth_b transistor may be connected to the second electrode of the fifth_a transistor, and a second electrode of the fifth_b transistor may be electrically connected to the fifth node N5.

The sixth transistor T6 may be turned on by the emission control signal EM of the emission control line EML and electrically connect the driving voltage line VDL and the first node N1. A gate of the sixth transistor T6 may be electrically connected to the emission control line EML, a second electrode of the sixth transistor T6 may be electrically connected to the driving voltage line VDL, and a first electrode of the sixth transistor T6 may be electrically connected to the first node N1.

The seventh transistor T7 may be turned on by the emission control signal EM of the emission control line EML and electrically connect the second node N2 and the fourth node N4, which is a first node of the light emitting element ED. A gate of the seventh transistor T7 may be electrically connected to the emission control line EML, a second electrode of the seventh transistor T7 may be electrically connected to the second node N2, and a first electrode of the seventh transistor T7 may be electrically connected to the fourth node N4.

The eighth transistor T8 may be turned on by the fifth gate signal EB of the fifth gate line EBL and may electrically connect the fourth node N4, which is the first electrode of the light emitting element ED, and the second initialization voltage line VIL2. The eighth transistor T8 may be turned on based on the fifth gate signal, thereby discharging the first electrode of the light emitting element ED to the second initialization voltage VIT2. A gate electrode of the eighth transistor T8 may be electrically connected to the fifth gate line EBL, a second electrode of the eighth transistor T8 may be electrically connected to the fourth node N4, and a first electrode of the eighth transistor T8 may be electrically connected to the second initialization voltage line VIL2. The second initialization voltage line VIL2 may transmit the second initialization voltage VIT2.

The ninth transistor T9 may be turned on by the fifth gate signal EB of the fifth gate line EBL and electrically connect the bias voltage line VBL and the first node N1. The ninth transistor T9 may be turned on based on the fifth gate signal EB, thereby supplying the bias voltage VB to the first node N1. The ninth transistor T9 may improve hysteresis of the first transistor T1 by supplying the bias voltage VB to the second electrode of the first transistor T1 connected to the first node N1. A gate electrode of the ninth transistor T9 may be electrically connected to the fifth gate line EBL, a second electrode of the ninth transistor T9 may be electrically connected to the bias voltage line VBL, and a first electrode of the ninth transistor T9 may be electrically connected to the first node N1.

The tenth transistor T10 may be turned on by the second gate signal GC of the second and third gate lines GCL and electrically connect the driving voltage line VDL and the first node N1. For example, a gate electrode of the tenth transistor T10 may be electrically connected to the second and third gate lines GCL, a second electrode of the tenth transistor T10 may be connected to the driving voltage line VDL, and a first electrode of the tenth transistor T10 may be electrically connected to the first node N1. The tenth transistor T10 may be turned on by the second gate signal GC of the second and third gate lines GCL and electrically connect the driving voltage line VDL and the first node N1.

When the sixth transistor T6, the first transistor T1, and the seventh transistor T7 are all turned on, the driving current may be supplied to the light emitting element ED.

Each of the first to tenth transistors T1 to T10 may include a silicon-based active layer. For example, each of the first to tenth transistors T1 to T10 may be a p-channel transistor including an active layer made of low temperature polycrystalline silicon (LTPS). The active layer made of low temperature polycrystalline silicon may have high electron mobility and excellent or suitable turn-on characteristics. Therefore, the display device 10 may stably and efficiently drive the plurality of pixels by including the transistors with excellent or suitable turn-on characteristics. Each of the first to tenth transistors T1 to T10 may output current flowing into the first electrode to the second electrode based on a gate-on voltage (e.g., a gate low voltage at a p-channel transistor) applied to the gate electrode of the corresponding transistor.

The first capacitor C1 may be electrically connected between the driving voltage line VDL and the fifth node N5. For example, a first electrode of the first capacitor C1 may be electrically connected to the fifth node N5, and a second electrode of the first capacitor C1 may be electrically connected to the driving voltage line VDL. The first capacitor C1 may maintain a potential difference between the driving voltage line VDL and the gate electrode of the first transistor T1.

The second capacitor C2 may be electrically connected between the fifth node N5 and the third node N3. For example, a first electrode of the second capacitor C2 may be electrically connected to the fifth node N5, and a second electrode of the second capacitor C2 may be electrically connected to the third node N3. The second capacitor C2 may maintain the data voltage supplied from the data line DL2 through the second transistor T2 for one frame period.

In the display device according to an embodiment of the present specification, the first transistor T1 which is a driving transistor and the second to tenth transistors T2 to T10 which are switching transistors may be arranged in the pixel circuit. Among the transistors, a line for applying a signal or voltage supplied to the gate electrodes of the eighth transistor T8 and the ninth transistor T9 may be included in a first gate metal layer, and a line for applying a signal or voltage supplied to the gate electrodes of the remaining switching transistors T2, T3, T4, T5, T6, T7, and T10 may be included in a third gate metal layer.

According to one embodiment, the lines for applying the signal or voltage supplied to the gate electrodes of the remaining switching transistors T2, T3, T4, T5, T6, T7, and T10 described above may be included in the third gate metal layer, and each signal or voltage may be supplied to the gate electrode via the connection metal layer.

The line for applying the signal or voltage supplied to the gate electrodes of the switching transistors T2, T3, T4, T5, T6, T7, and T10 may be a scan line or a gate line and may be arranged to intersect the data line DL that is arranged to extend in the second direction in the display device. For example, the line for applying the signal or voltage supplied to the gate electrodes of the switching transistors T2, T3, T4, T5, T6, T7, and T10 arranged to extend in the first direction intersecting the second direction.

The display device according to an embodiment may reduce a use of the connection metal layer by utilizing the third gate metal layer arranged to extend in the first direction. As the use of the connection metal layer is reduced, an additional design area for the connection metal layer among the lines included in the pixel circuit PC may be made available.

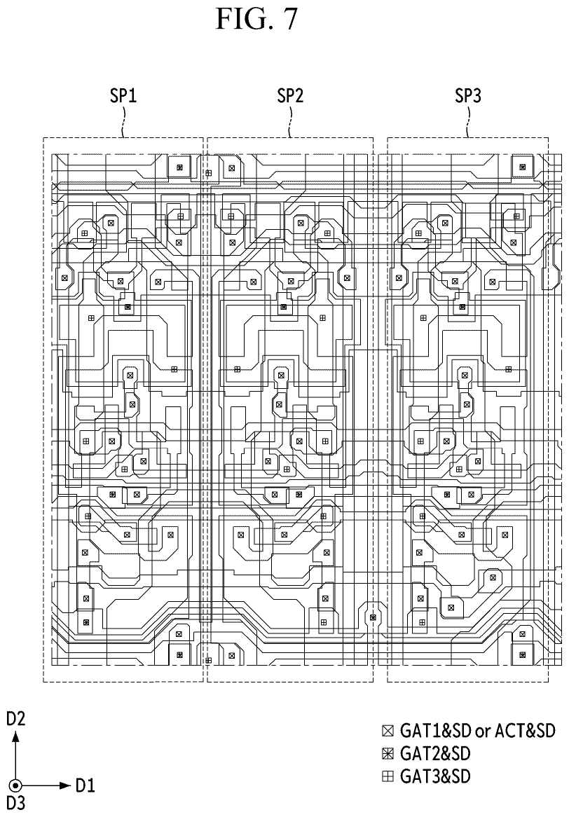

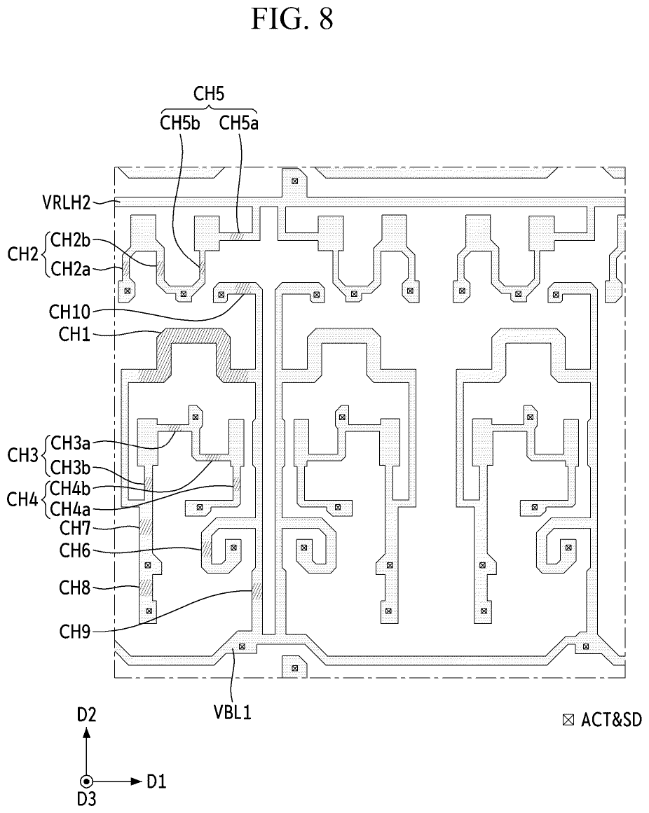

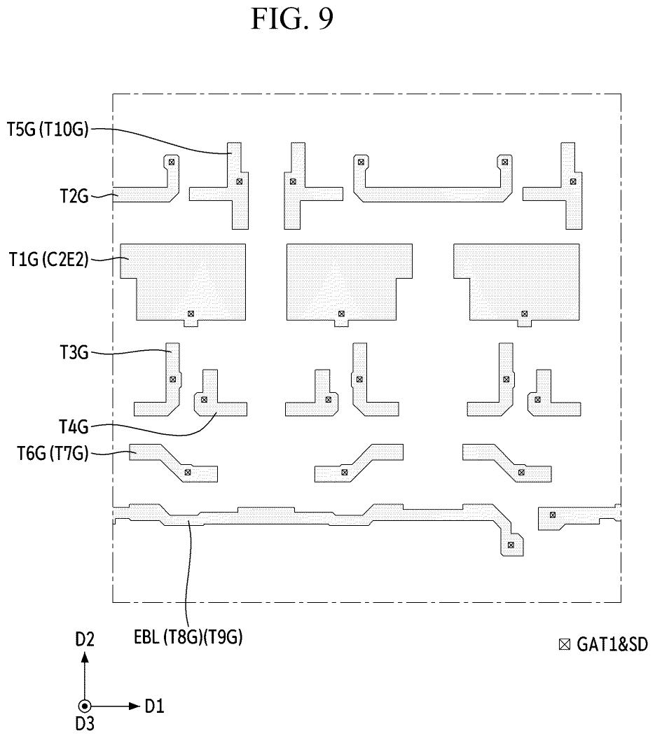

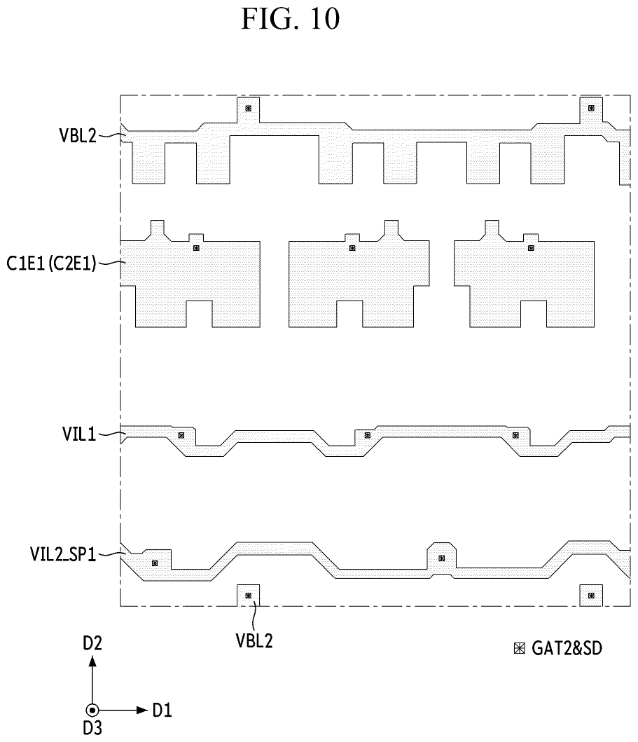

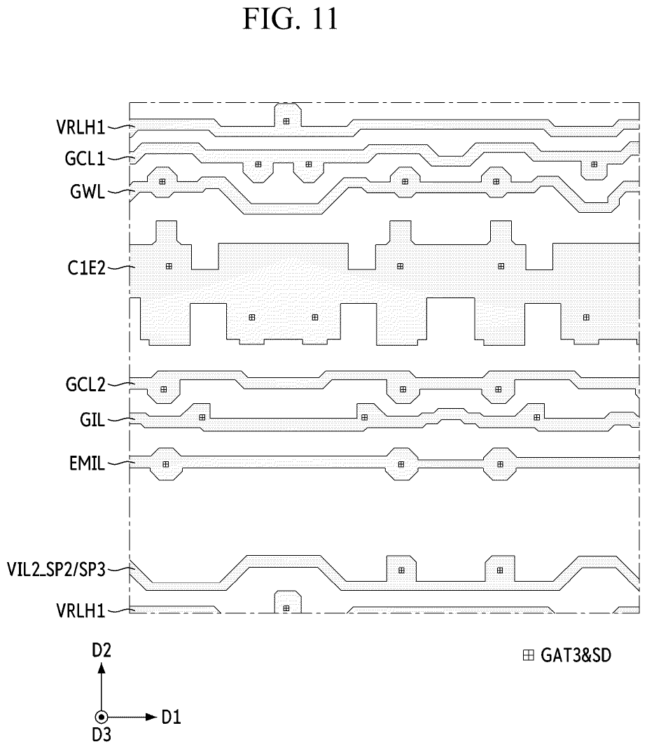

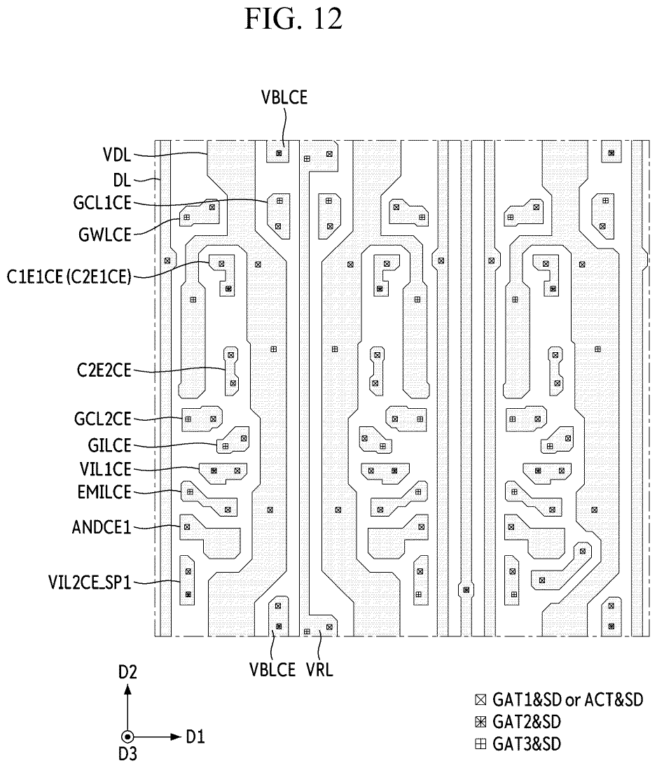

FIG. 7 is a plan view of lines included in one pixel circuit according to an embodiment of the present specification. FIG. 8 is a plan view of an active layer included in one pixel circuit according to an embodiment of the present specification. FIG. 9 is a plan view of a first gate metal layer included in one pixel circuit according to an embodiment of the present specification. FIG. 10 is a plan view of a second gate metal layer included in one pixel circuit according to an embodiment of the present specification. FIG. 11 is a plan view of a third gate metal layer included in one pixel circuit according to an embodiment of the present specification. FIG. 12 is a plan view of a connection metal layer included in one pixel circuit according to an embodiment of the present specification.

Hereinafter, a transistor includes a first electrode, a second electrode, and a channel portion arranged between the first electrode and the second electrode. For example, the second transistor may include a first electrode of the second transistor, a second electrode of the second transistor, and a channel portion of the second transistor arranged between the first electrode of the second transistor and the second electrode of the second transistor. As described above, the first electrode and the second electrode are either the source or the drain of the transistor and may not overlap each other.

In some embodiments, that an arbitrary voltage may be applied to the channel portion indicates that a voltage may be applied to the second electrode (or first electrode) through the first electrode (or second electrode) while the transistor is turned on.

In some embodiments, that an arbitrary line may be connected to the channel portion indicates that the arbitrary line may be connected to the first electrode (or second electrode) of the corresponding transistor. For example, the description that “a bias voltage connection electrode may be connected to the channel portion of the ninth transistor through a specific contact hole” may include the meaning that “the bias voltage connection electrode may be connected to the second electrode (or first electrode) of the ninth transistor through a specific contact hole.”

Referring to FIG. 7, one pixel circuit according to an embodiment may include a first sub-pixel SP1, a second sub-pixel SP2, and a third sub-pixel SP3. The first sub-pixel SP1, the second sub-pixel SP2, and the third sub-pixel SP3 may implement a first color, a second color, and a third color, respectively. The first color, the second color, and the third color may be any one selected from the group consisting of red, green, and blue so as not to overlap each other.

Referring to FIG. 8, the active layer may include a second horizontal reference voltage line VRLH2 and a first bias voltage line VBL1.

The second horizontal reference voltage line VRLH2 may be electrically connected to the reference voltage line VRL included in the connection metal layer. The second horizontal reference voltage line VRLH2 may be electrically connected to a first horizontal reference voltage line VRLH1 included in the third gate metal layer through the reference voltage line VRL. A reference voltage may be commonly applied to both the first horizontal reference voltage line VRLH1 and the second horizontal reference voltage line VRLH2.

The second horizontal reference voltage line VRLH2 may be physically connected to a channel portion CH5 of the fifth transistor T5. When the fifth transistor T5 is configured as a dual gate transistor, the channel portion CH5 of the fifth transistor T5 may include a channel portion CH5a of a fifth_a transistor T5a and a channel portion CH5b of a fifth_b transistor T5b. In this case, the second horizontal reference voltage line VRLH2 may be connected to the channel portion CH5b of the fifth_b transistor T5b, and the channel portion CH5b of the fifth_b transistor T5b may be physically connected to the channel portion CH5a of the fifth_a transistor T5a.

The channel portion CH5 of the fifth transistor T5 may be physically connected to a channel portion CH2 of the second transistor T2. When the second transistor T2 is configured as a dual gate transistor, the channel portion CH2 of the second transistor T2 may include a channel portion CH2a of a second_a transistor T2a and a channel portion CH2b of a second_b transistor T2b. In this case, the channel portion CH5b of the fifth_b transistor T5b may be connected to the channel portion CH2b of the second_b transistor T2b, and the channel portion CH2b of the second_b transistor T2b may be physically connected to the channel portion CH2a of the second_a transistor T2a.

The first bias voltage line VBL1 may be physically connected to a channel portion CH9 of the ninth transistor T9. The channel portion CH9 of the ninth transistor T9 may be physically connected to a channel portion CH1 of the first transistor T1, a channel portion CH10 of the tenth transistor T10, and a channel portion CH6 of the sixth transistor T6.

The channel portion CH1 of the first transistor T1 may be physically connected to a channel portion CH7 of the seventh transistor T7 and a channel portion CH3 of the third transistor T3.

The channel portion CH7 of the seventh transistor T7 may be physically connected to a channel portion CH8 of the eighth transistor T8.

When the third transistor T3 is configured as a dual gate transistor, the channel portion CH3 of the third transistor T3 may include a channel portion CH3a of a third_a transistor T3a and a channel portion CH3b of a third_b transistor T3b. The channel portion CH3b of the third_b transistor T3b may be physically connected to the channel portion CH7 of the seventh transistor T7. The channel portion CH3a of the third_a transistor T3a may be physically connected to the channel portion CH3b of the third_b transistor T3b. The channel portion CH3a of the third_a transistor T3a may be physically connected to the channel portion CH4 of the fourth transistor T4.

When the fourth transistor T4 is configured as a dual gate transistor, the channel portion CH4 of the fourth transistor T4 may include a channel portion CH4a of a fourth_a transistor T4a and a channel portion CH4b of a fourth_b transistor T4b. The channel portion CH4b of the fourth_b transistor T4b may be physically connected to the channel portion CH3 of the third transistor T3. The channel portion CH4a of the fourth_a transistor T4a may be physically connected to the channel portion CH4b of the fourth_b transistor T4b.

Referring to FIG. 9, the first gate metal layer arranged on the active layer may include a gate electrode T2G of the second transistor T2, a gate electrode T5G of the fifth transistor T5 (or a gate electrode T10G of the tenth transistor T10), a gate electrode T1G of the first transistor T1, a gate electrode T3G of the third transistor T3, a gate electrode T4G of the fourth transistor T4, a gate electrode T6G of the sixth transistor T6 (or a gate electrode T7G of the seventh transistor T7), and a fifth gate line EBL. The fifth gate line EBL may be a gate electrode T8G of the eighth transistor T8. The fifth gate line EBL may be a gate electrode T9G of the ninth transistor T9.

Each gate electrode or gate line may be arranged to be spaced apart from each other. A fifth gate signal may be applied to the fifth gate line EBL.

The second gate electrodes included in each of the second sub-pixel SP2 and the third sub-pixel SP3 may be formed to be physically connected to each other. In some embodiments, the second gate electrodes may be formed integrally with each other.

The fifth gate line EBL may be arranged to extend in the first direction. The fifth gate line EBL may be divided into a plurality of gate lines. The plurality of gate lines divided as the fifth gate line EBL may be electrically connected to each other through a plurality of contact holes.

Referring to the circuit diagram described above, a second gate signal may be applied to all of the gate electrode T5G of the fifth transistor T5, the gate electrode T10G of the tenth transistor T10, and the gate electrode T3G of the third transistor T3. In some embodiments, the gate line may include a plurality of lines that apply the second gate signal. Therefore, the gate line that applies the second gate signal may include a second gate line GCL1 and a third gate line GCL2. As described below, the second gate line GCL1 and the third gate line GCL2 may be included in the third gate metal layer.

The same second gate signal may be applied to all of the gate electrode T5G of the fifth transistor T5, the gate electrode T10G of the tenth transistor T10, and the gate electrode T3G of the third transistor T3, but in plan view, the second gate line GCL1 that applies the second gate signal to the gate electrode T5G of the fifth transistor T5 and the third gate line GCL2 that applies the second gate signal to the gate electrode T3G of the third transistor T3 may be arranged to be physically separated from each other. Both the second gate line GCL1 and the third gate line GCL2 may supply the second gate signal.

In some embodiments, the gate line that applies the second gate signal to the gate electrode T5G of the fifth transistor T5 and the gate line that applies the second gate signal to the gate electrode T10G of the tenth transistor T10 may both be common as the second gate line GCL1. The second gate line GCL1 and the third gate line GCL2 may be included in the third gate metal layer.

The gate electrode T5G of the fifth transistor T5 and the gate electrode T10G of the tenth transistor T10, which receive the second gate signal from the second gate line GCL1 included in the third gate metal layer, may be arranged to be physically connected to each other in the third gate metal layer. The gate electrode T5G of the fifth transistor T5 may be physically connected to the gate electrode T10G of the tenth transistor T10.

The gate electrode T5G of the fifth transistor T5 (or the gate electrode T10G of the tenth transistor T10) may include a plurality of protrusions. When the fifth transistor T5 is configured as a dual gate transistor, any two of the plurality of protrusions may function as the gate electrode of the fifth_a transistor T5a and the gate electrode of the fifth_b transistor T5b, respectively, and any one of them may function as the gate electrode T10G of the tenth transistor T10. By designing the gate electrodes of the transistors that receive the same gate signal to be shared with each other rather than configured separately, additional design space for the pixel circuit may be made available.

This configuration in which the gate electrodes are physically connected to each other to reduce the number of gate electrodes when the same gate signal is supplied may also be applied to the sixth transistor T6 and the seventh transistor T7.

Referring to the circuit diagram described above, an emission control signal may be applied to both the gate electrode T6G of the sixth transistor T6 and the gate electrode T7G of the seventh transistor T7. As described below, an emission control line EML for applying the emission control signal may be included in the third gate metal layer.

In some embodiments, the emission control line EML that applies the emission control signal to the gate electrode T6G of the sixth transistor T6 and the emission control line EML that applies the emission control signal to the gate electrode T7G of the seventh transistor T7 may be the same.

The gate electrode T6G of the sixth transistor T6 and the gate electrode T7G of the seventh transistor T7, which receive the emission control signal from the emission control line EML included in the third gate metal layer, may be arranged to be physically connected to each other in the first gate metal layer. The gate electrode T6G of the sixth transistor T6 may be physically connected to the gate electrode T7G of the seventh transistor T7.

In the second transistor T2, the third transistor T3, the fourth transistor T4, and the fifth transistor T5 which may be configured as the dual gate transistors, the gate electrode T2G of the second transistor T2, the gate electrode T3G of the third transistor T3, the gate electrode T4G of the fourth transistor T4, and the gate electrode T5G of the fifth transistor T5 may each include two protrusions.

The plurality of gate electrodes included in the first gate metal layer may overlap the active layer in the thickness direction. The active layer overlapping the gate electrode may become the channel portion of each transistor.

For example, at least a portion of the active layer overlapping the gate electrode T1G of the first transistor T1 may function as the channel portion CH1 of the first transistor T1. At least a portion of the active layer overlapping the gate electrode T2G of the second transistor T2 may function as the channel portion CH2 of the second transistor T2. At least a portion of the active layer overlapping the gate electrode T3G of the third transistor T3 may function as the channel portion CH3 of the third transistor T3. At least a portion of the active layer overlapping the gate electrode T4G of the fourth transistor T4 may function as the channel portion CH4 of the fourth transistor T4. At least a portion of the active layer overlapping the gate electrode T5G of the fifth transistor T5 may function as the channel portion CH5 of the fifth transistor T5. At least a portion of the active layer overlapping the gate electrode T6G of the sixth transistor T6 may function as the channel portion CH6 of the sixth transistor T6. At least a portion of the active layer overlapping the gate electrode T7G of the seventh transistor T7 may function as the channel portion CH7 of the seventh transistor T7. At least a portion of the active layer overlapping the gate electrode T8G of the eighth transistor T8 may function as the channel portion CH8 of the eighth transistor T8. At least a portion of the active layer overlapping the gate electrode T9G of the ninth transistor T9 may function as the channel portion CH9 of the ninth transistor T9. At least a portion of the active layer overlapping the gate electrode T10G of the tenth transistor T10 may function as the channel portion CH10 of the tenth transistor T10.

The gate electrode T1G of the first transistor T1 may function as a second electrode C2E2 of the second capacitor. The second electrode C2E2 of the second capacitor included in the first gate metal layer may be arranged to be spaced apart for each sub-pixel.

Referring to FIG. 10, the second gate metal layer arranged on the first gate metal layer may include a second bias voltage line VBL2, a first electrode C1E1 of a first capacitor (or, a first electrode C2E1 of a second capacitor), a first initialization voltage line VIL1, and a second initialization voltage line VIL2_SP1 connected to the first sub-pixel SP1.

The second electrode C2E2 of the second capacitor included in the first gate metal layer may form the second capacitor C2 with the first electrode C2E1 of the second capacitor included in the second gate metal layer. The first electrode C2E1 of the second capacitor included in the second gate metal layer may be arranged to be spaced apart for each sub-pixel.

The second bias voltage line VBL2 may be electrically connected to the first bias voltage line VBL1 included in the active layer. A bias voltage may be commonly applied to both the first bias voltage line VBL1 and the second bias voltage line VBL2.

The first initialization voltage line VIL1 may be arranged to extend in the first direction. The first initialization voltage may be applied to the first initialization voltage line VIL1.

The second initialization voltage line VIL2_SP1 connected to the first sub-pixel SP1 may be arranged to extend in the first direction. The second initialization voltage may be applied to the second initialization voltage line VIL2_SP1 connected to the first sub-pixel SP1.

FIG. 11, the third gate metal layer arranged on the second gate metal layer may include a first horizontal reference voltage line VRLH1, a second gate line GCL1, a first gate line GWL, a second electrode C1E2 of a first capacitor, a third gate line GCL2, a fourth gate line GIL, an emission control line EML, and a second initialization voltage line VIL2_SP2/SP3 connected to the second sub-pixel SP2 and the third sub-pixel SP3. These may all be arranged to extend in the first direction.

The first electrode C1E1 of the first capacitor included in the second gate metal layer may form the first capacitor C1 with the second electrode C1E2 of the first capacitor included in the third gate metal layer. The second electrode C1E2 of the first capacitor included in the third gate metal layer may be commonly formed in each sub-pixel.

The first horizontal reference voltage line VRLH1 may be electrically connected to the reference voltage line VRL included in the connection metal layer. The first horizontal reference voltage line VRLH1 may be electrically connected to a second horizontal reference voltage line VRLH2 included in the active layer through the reference voltage line VRL. A reference voltage may be commonly applied to both the first horizontal reference voltage line VRLH1 and the second horizontal reference voltage line VRLH2.

Both the second gate line GCL1 and the third gate line GCL2 may supply the second gate signal.

The second gate line GCL1 may supply the second gate signal to the gate electrode T5G of the fifth transistor T5 (or, the gate electrode T10G of the tenth transistor T10) included in the first gate metal layer through a second gate connection electrode GCL1CE included in the connection metal layer.

The third gate line GCL2 may supply the second gate signal to the gate electrode T3G of the third transistor T3 included in the first gate metal layer through a third gate connection electrode GCL2CE included in the connection metal layer.

The first gate line GWL may supply a first gate signal. The first gate line GWL may supply the first gate signal to the gate electrode T2G of the second transistor T2 included in the first gate metal layer through a first gate connection electrode GWLCE included in the connection metal layer.

The fourth gate line GIL may supply a fourth gate signal. The fourth gate line GIL may supply the fourth gate signal to the gate electrode T4G of the fourth transistor T4 included in the first gate metal layer through a fourth gate connection electrode GILCE included in the connection metal layer.

The emission control line EML may supply an emission control signal. The emission control line EML may supply the emission control signal to the gate electrode T6G of the sixth transistor T6 (or, the gate electrode T7G of the seventh transistor T7) included in the first gate metal layer through an emission control connection electrode EMLCE included in the connection metal layer.

The second initialization voltage may be applied to the second initialization voltage line VIL2_SP2/SP3 connected to the second sub-pixel SP2 and the third sub-pixel SP3.

Referring to FIG. 12, the connection metal layer arranged on the third gate metal layer may include a data line DL, a driving voltage line VDL, a bias voltage connection electrode VBLCE, a first gate connection electrode GWLCE, a second gate connection electrode GCL1CE, a first capacitor C1 connection electrode, a second capacitor C2 connection electrode, a third gate connection electrode GCL2CE, a fourth gate connection electrode GILCE, a first initialization voltage connection electrode VIL1CE, an emission control connection electrode EMLCE, a first anode connection electrode ANDCE1, and a second initialization voltage connection electrode VIL2CE_SP1 connected to the first sub-pixel SP1.

The data line DL may be arranged to extend in the second direction intersecting the first direction. The data line DL may supply a data voltage to the channel portion CH2 of the second transistor T2 included in the active layer.

The driving voltage line VDL may be electrically connected to the channel portion CH6 of the sixth transistor T6 and the channel portion CH10 of the tenth transistor T10 included in the active layer, and the second electrode C1E2 of the first capacitor included in the third gate metal layer. The driving voltage line VDL may supply a driving voltage to the channel portion CH6 of the sixth transistor T6, the channel portion CH10 of the tenth transistor T10, and the second electrode C1E2 of the first capacitor. The driving voltage line VDL may be connected to the second electrode C1E2 of the first capacitor through a plurality of contact holes.

The bias voltage connection electrode VBLCE may be electrically connected to the second bias voltage line VBL2 included in the second gate metal layer and the first bias voltage line VBL1 included in the active layer. The bias voltage connection electrode VBLCE may supply a bias voltage to the channel portion CH9 of the ninth transistor T9 included in the active layer.

The first gate connection electrode GWLCE may be electrically connected to the first gate line GWL included in the third gate metal layer and the gate electrode T2G of the second transistor T2 included in the first gate metal layer. The first gate connection electrode GWLCE may receive a first gate signal from the first gate line GWL and apply the first gate signal to the gate electrode T2G of the second transistor T2.

The second gate connection electrode GCL1CE may be electrically connected to the second gate line GCL1 included in the third gate metal layer and the gate electrode T5G of the fifth transistor T5 (or the gate electrode T10G of the tenth transistor T10) included in the first gate metal layer. The second gate connection electrode GCL1CE may receive a second gate signal from the second gate line GCL1 and apply the second gate signal to the gate electrode T5G of the fifth transistor T5 (or the gate electrode T10G of the tenth transistor T10).

The first capacitor C1 connection electrode may be electrically connected to the second electrode of the second transistor T2 (or the second electrode of the fifth transistor T5) included in the active layer and the first electrode C1E1 of the first capacitor (or the first electrode C2E1 of the second capacitor) included in the second gate metal layer.

The second capacitor C2 connection electrode may be electrically connected to the gate electrode T1G of the first transistor T1 (or the second electrode C2E2 of the second capacitor) included in the first gate metal layer and the first electrode of the third transistor T3 (or the second electrode of the fourth transistor T4) included in the active layer.

The third gate connection electrode GCL2CE may be electrically connected to the third gate line GCL2 included in the third gate metal layer and the gate electrode T3G of the third transistor T3 included in the first gate metal layer. The third gate connection electrode GCL2CE may receive a second gate signal from the third gate line GCL2 and apply the second gate signal to the gate electrode T3G of the third transistor T3.

The fourth gate connection electrode GILCE may be electrically connected to the fourth gate line GIL included in the third gate metal layer and the gate electrode T4G of the fourth transistor T4 included in the first gate metal layer. The fourth gate connection electrode GILCE may receive a fourth gate signal from the fourth gate line GIL and apply the fourth gate signal to the gate electrode T4G of the fourth transistor T4.

The first initialization voltage connection electrode VIL1CE may be electrically connected to the first initialization voltage line VIL1 included in the second gate metal layer and the channel portion CH4 of the fourth transistor T4 included in the active layer. The first initialization voltage connection electrode VIL1CE may receive a first initialization voltage from the first initialization voltage line VIL1 and supply the first initialization voltage to the channel portion CH4 of the fourth transistor T4.

The emission control connection electrode EMLCE may be electrically connected to the emission control line EML included in the third gate metal layer and the gate electrode T6G of the sixth transistor T6 (or the gate electrode T7G of the seventh transistor T7) included in the first gate metal layer. The emission control connection electrode EMLCE may receive an emission control signal from the emission control line EML and apply the emission control signal to the gate electrode T6G of the sixth transistor T6 (or the gate electrode T7G of the seventh transistor T7).

The first anode connection electrode ANDCE1 may be electrically connected to the first electrode T7E1 of the seventh transistor T7 (or the second electrode T8E2 of the eighth transistor T8) included in the active layer and a second anode connection electrode arranged on the connection metal layer.

The second initialization voltage connection electrode VIL2CE_SP1 connected to the first sub-pixel SP1 may be electrically connected to the second initialization voltage line VIL2_SP1 connected to the first sub-pixel SP1 included in the second gate metal layer and to the channel portion CH8 of the eighth transistor T8 included in the active layer. The second initialization voltage connection electrode VIL2CE_SP1 connected to the first sub-pixel SP1 may receive a second initialization voltage from the second initialization voltage line VIL2_SP1 connected to the first sub-pixel SP1 and supply the second initialization voltage to the channel portion CH8 of the eighth transistor T8.

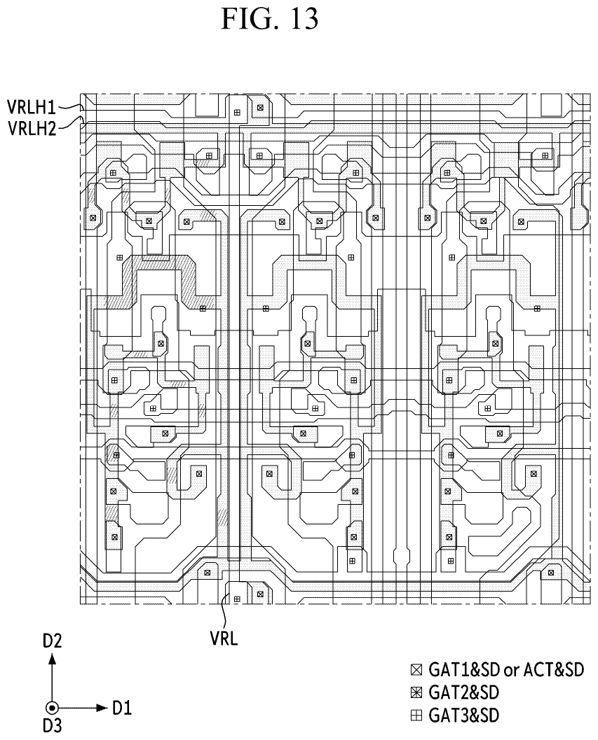

FIG. 13 is a plan view of a path along which a reference voltage is applied in one pixel circuit according to an embodiment of the present specification.

Referring to FIG. 13, the connection metal layer may further include a reference voltage line VRL. The reference voltage line VRL may be electrically connected to the second horizontal reference voltage line VRLH2 included in the active layer and the first horizontal reference voltage line VRLH1 included in the third gate metal layer. The reference voltage line VRL may supply a reference voltage to the first horizontal reference voltage line VRLH1 and the second horizontal reference voltage line VRLH2.

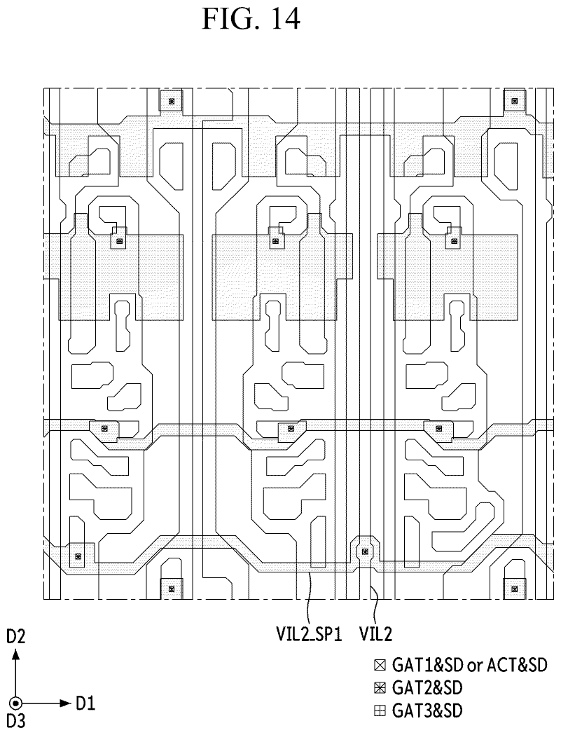

FIG. 14 is a plan view of a path along which an initialization voltage is applied to a first sub-pixel SP1 in one pixel circuit according to an embodiment of the present specification.

Referring to FIG. 14, the connection metal layer may further include a second horizontal reference voltage line VIL2. The second horizontal reference voltage line VIL2 may be electrically connected to the second initialization voltage line VIL2_SP1 connected to the first sub-pixel SP1 included in the second gate metal layer and the second initialization voltage line VIL2_SP2/SP3 connected to the second sub-pixel SP2 and the third sub-pixel SP3 included in the third gate metal layer. The second initialization voltage line may supply a second initialization voltage to the second initialization voltage line VIL2_SP1 connected to the first sub-pixel SP1 and the second initialization voltage line VIL2_SP2/SP3 connected to the second sub-pixel SP2 and the third sub-pixel SP3.

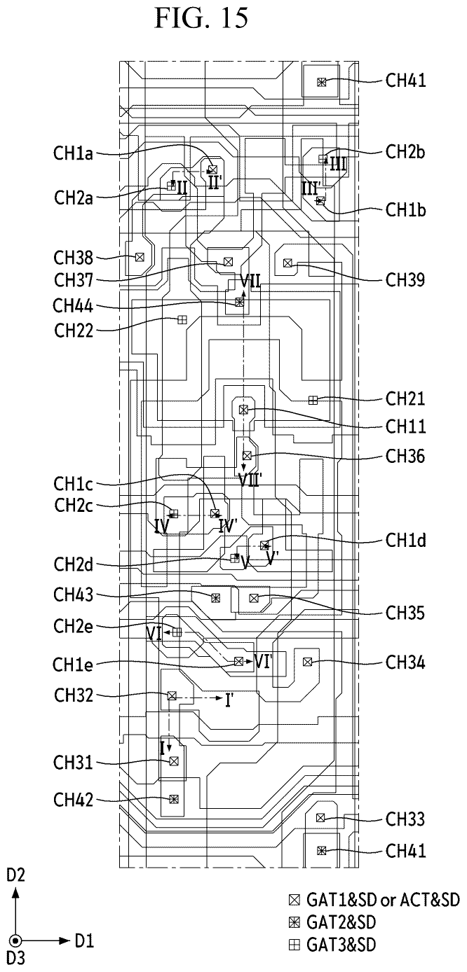

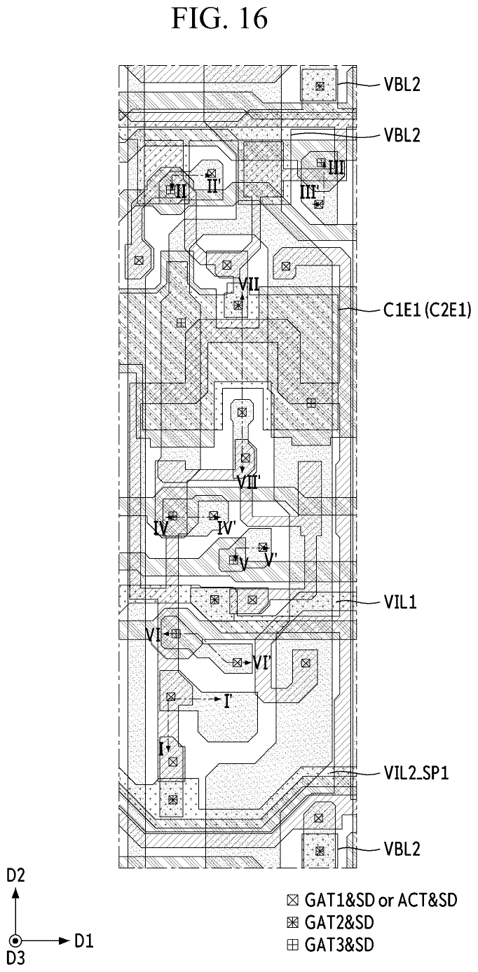

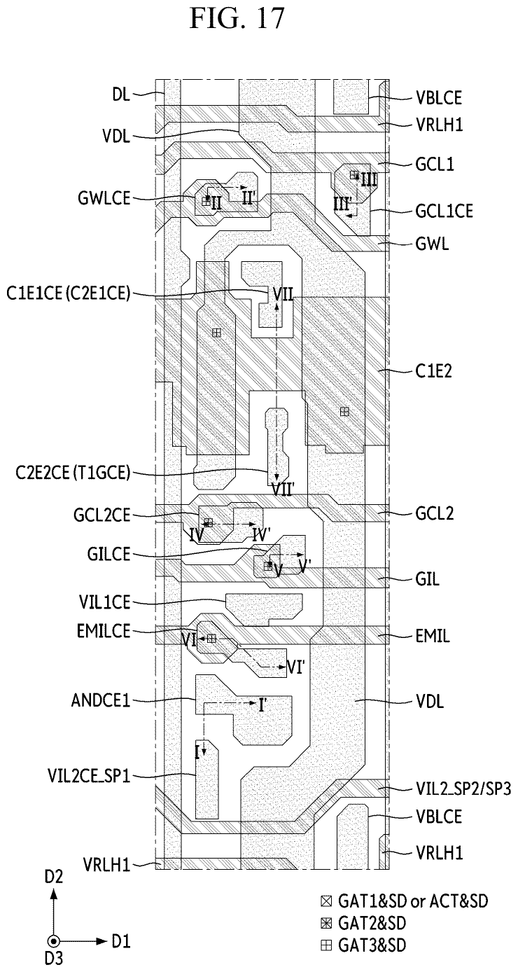

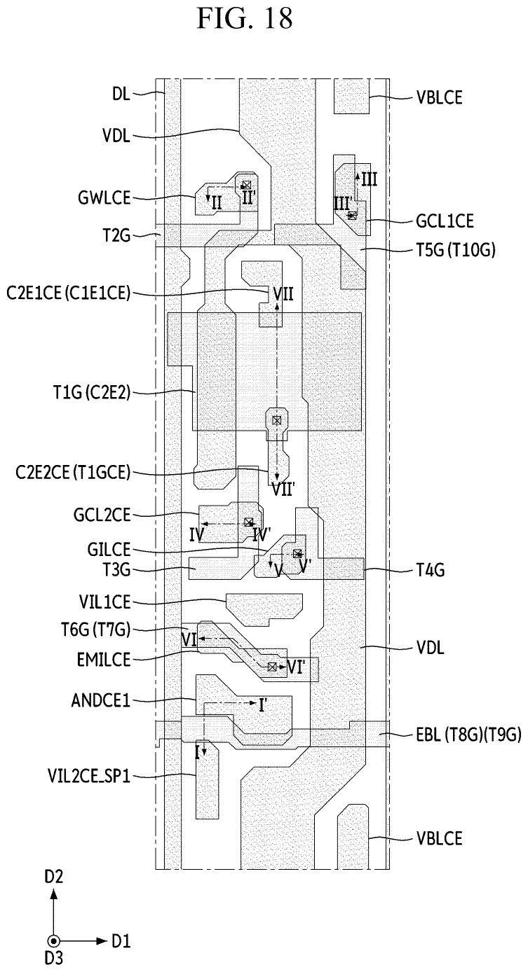

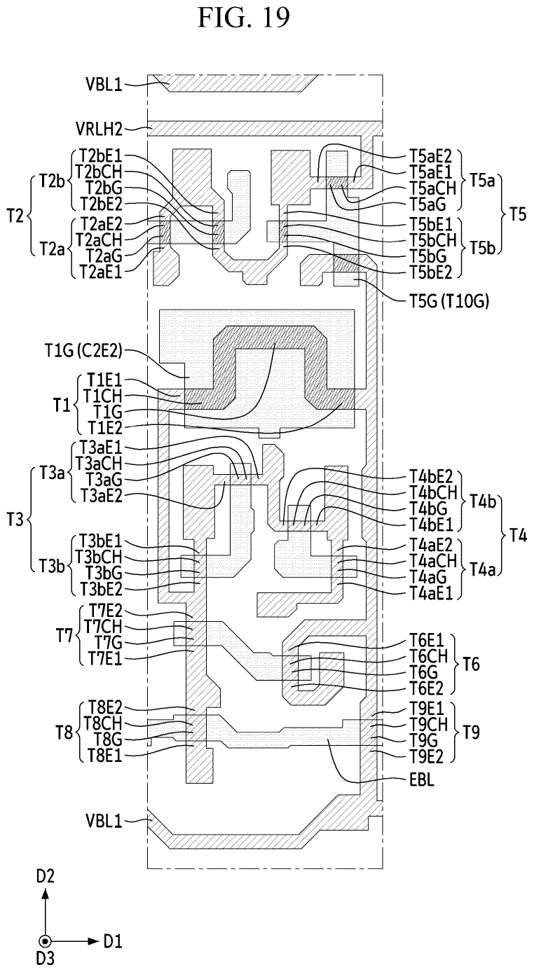

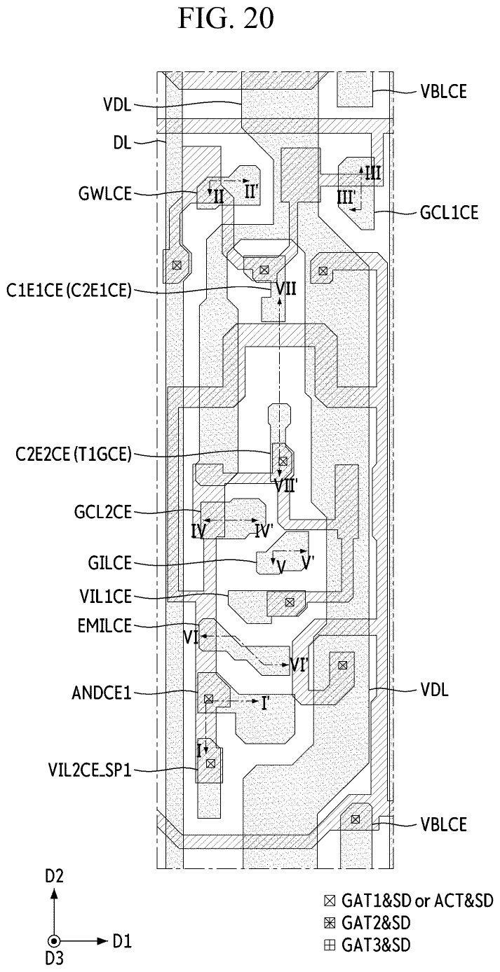

FIG. 15 is a plan view of all lines included in the first sub-pixel according to an embodiment of the present specification. FIG. 16 is a plan view of an active layer, a second gate metal layer, and a connection metal layer included in the first sub-pixel according to an embodiment of the present specification. FIG. 17 is a plan view of a third gate metal layer and a connection metal layer included in the first sub-pixel according to an embodiment of the present specification. FIG. 18 is a plan view of a connection metal layer and a first gate metal layer included in the first sub-pixel according to an embodiment of the present specification. FIG. 19 is a plan view of a first gate metal layer and an active layer included in the first sub-pixel according to an embodiment of the present specification. FIG. 20 is a plan view of an active layer and a connection metal layer included in the first sub-pixel according to an embodiment of the present specification.

Referring to FIG. 15, the first sub-pixel SP1 may include a plurality of contact holes. The plurality of contact holes included in the first sub-pixel SP1 may also be formed in the second sub-pixel SP2 and the third sub-pixel SP3 with their positions, etc. symmetrical or deformed.

The plurality of contact holes may include a first contact hole, a second contact hole, a third contact hole, and a fourth contact hole.

Referring to FIG. 19, the configuration of the active layer is illustrated when the second transistor T2, the third transistor T3, the fourth transistor T4, and the fifth transistor T5 are implemented as dual-gate transistors. In some embodiments, the dual-gate transistor may also correspond to a transistor having a single gate. For example, the first electrode of the second transistor T2 may be a first electrode T2aE1 of the second_a transistor T2a, and the second electrode of the second transistor T2 may be a second electrode T2bE2 of the second_b transistor T2b. For example, the first electrode of the third transistor T3 may be a first electrode T3aE1 of the third_a transistor T3a, and the second electrode of the third transistor T3 may be a second electrode T3bE2 of the third_b transistor T3b. For example, the first electrode of the fourth transistor T4 may be a first electrode T4aE1 of the fourth_a transistor T4a, and the second electrode of the fourth transistor T4 may be a second electrode T4bE2 of the fourth_b transistor T4b. For example, the first electrode of the fifth transistor T5 may be a first electrode T5aE1 of the fifth_a transistor T5a, and the second electrode of the fifth transistor T5 may be a second electrode T5bE2 of the fifth_b transistor T5b.

Referring to FIGS. 15 and 18, the first contact hole may connect the configuration included in the connection metal layer and the configuration included in the first gate metal layer. At least a portion of the first contact hole may connect the connection electrode included in the connection metal layer and the gate electrode included in the first gate metal layer. The first contact hole may include a first_a contact hole CH1a, a first_b contact hole CH1b, a first_c contact hole CH1c, a first_d contact hole CH1d, and a first_e contact hole CH1e.

The first_a contact hole CH1a may electrically connect the first gate connection electrode GWLCE included in the connection metal layer and the gate electrode T2G of the second transistor T2 included in the first gate metal layer.

The first_b contact hole CH1b may electrically connect the second gate connection electrode GCL1CE included in the connection metal layer and the gate electrode T5G of the fifth transistor T5 (or the gate electrode T10G of the tenth transistor T10) included in the first gate metal layer.

The first_c contact hole CH1c may electrically connect the third gate connection electrode GCL2CE included in the connection metal layer and the gate electrode T3G of the third transistor T3 included in the first gate metal layer.

The first_d contact hole CH1d may electrically connect the fourth gate connection electrode GILCE included in the connection metal layer and the gate electrode T4G of the fourth transistor T4 included in the first gate metal layer.

The first_e contact hole CH1e may electrically connect the emission control connection electrode EMLCE included in the connection metal layer and the gate electrode T6G of the sixth transistor T6 (or the gate electrode T7G of the seventh transistor T7) included in the first gate metal layer.

The first contact hole may further include an eleventh contact hole CH11. The eleventh contact hole CH11 may electrically connect the connection electrode of the second capacitor C2 included in the connection metal layer and the gate electrode T1G of the first transistor T1 (or the second electrode C2E2 of the second capacitor) included in the first gate metal layer.

Referring to FIGS. 15 and 17, the second contact hole may connect the configuration included in the connection metal layer and the configuration included in the third gate metal layer. At least a portion of the second contact hole may connect the connection electrode included in the connection metal layer and the gate line or the emission control line EML included in the third gate metal layer. The second contact hole may include a second_a contact hole CH2a, a second_b contact hole CH2b, a second_c contact hole CH2c, a second_d contact hole CH2d, and a second_e contact hole CH2e.

The second_a contact hole CH2a may electrically connect the first gate connection electrode GWLCE included in the connection metal layer and the first gate line GWL included in the third gate metal layer.

The second_b contact hole CH2b may electrically connect the second gate connection electrode GCL1CE included in the connection metal layer and the second gate line GCL1 included in the third gate metal layer.

The second_c contact hole CH2c may electrically connect the third gate connection electrode GCL2CE included in the connection metal layer and the third gate line GCL2 included in the third gate metal layer.

The second_d contact hole CH2d may electrically connect the fourth gate connection electrode GILCE included in the connection metal layer and the fourth gate line GIL included in the third gate metal layer.

The second_e contact hole CH2e may electrically connect the emission control connection electrode EMLCE included in the connection metal layer and the emission control line EML included in the third gate metal layer.

The second contact hole may further include a twenty-first contact hole CH21 and a twenty-second contact hole CH22. Both the twenty-first contact hole CH21 and the twenty-second contact hole CH22 may electrically connect the driving voltage line VDL included in the connection metal layer and the second electrode C1E2 of the first capacitor included in the third gate metal layer. As described above, the driving voltage line VDL may be connected to the second electrode C1E2 of the first capacitor through the plurality of contact holes (the twenty-first contact hole CH21 and the twenty-second contact hole CH22).

Referring to FIGS. 15, 19, and 20, the third contact hole may connect the configuration included in the connection metal layer and the configuration included in the active layer. The third contact hole may include a thirty-first contact hole CH31, a thirty-second contact hole CH32, a thirty-third contact hole CH33, a thirty-fourth contact hole CH34, a thirty-fifth contact hole CH35, a thirty-sixth contact hole CH36, a thirty-seventh contact hole CH37, a thirty-eighth contact hole CH38, and a thirty-ninth contact hole CH39.

The thirty-first contact hole CH31 may electrically connect the second initialization voltage connection electrode VIL2CE_SP1 connected to the first sub-pixel SP1 included in the connection metal layer and the first electrode T8E1 of the eighth transistor T8 included in the active layer.

The thirty-second contact hole CH32 may electrically connect the first anode connection electrode ANDCE1 included in the connection metal layer and the first electrode T7E1 of the seventh transistor T7 (or the second electrode T8E2 of the eighth transistor T8) included in the active layer.

The thirty-third contact hole CH33 may electrically connect the bias voltage connection electrode VBLCE included in the connection metal layer and the channel portion CH9 of the ninth transistor T9 included in the active layer.

The thirty-fourth contact hole CH34 may electrically connect the driving voltage line VDL included in the connection metal layer and the channel portion CH6 of the sixth transistor T6 included in the active layer.

The thirty-fifth contact hole CH35 may electrically connect the first initialization voltage connection electrode VIL1CE included in the connection metal layer and the channel portion CH4 of the fourth transistor T4 included in the active layer.

The thirty-sixth contact hole CH36 may electrically connect the second capacitor C2 connection electrode included in the connection metal layer and the first electrode of the third transistor T3 (or the second electrode of the fourth transistor T4) included in the active layer.

The thirty-seventh contact hole CH37 may electrically connect the first capacitor C1 connection electrode included in the connection metal layer and the second electrode of the second transistor T2 (or the second electrode of the fifth transistor T5) included in the active layer.

The thirty-eighth contact hole CH38 may electrically connect the data line DL included in the connection metal layer and the channel portion CH2 of the second transistor T2 included in the active layer.

The thirty-ninth contact hole CH39 may electrically connect the driving voltage line VDL included in the connection metal layer and the channel portion CH1 of the first transistor T1 included in the active layer.

Referring to FIGS. 15, 16, and 18, the fourth contact hole may connect the configuration included in the connection metal layer and the configuration included in the second gate metal layer. The fourth contact hole may include a forty-first contact hole CH41, a forty-second contact hole CH42, a forty-third contact hole CH43, and a forty-fourth contact hole CH44.

The forty-first contact hole CH41 may electrically connect the bias voltage connection electrode VBLCE included in the connection metal layer and the second bias voltage line VBL2 included in the second gate metal layer.

The forty-second contact hole CH42 may electrically connect the second initialization voltage connection electrode VIL2CE_SP1 connected to the first sub-pixel SP1 included in the connection metal layer and the second initialization voltage line VIL2_SP1 connected to the first sub-pixel SP1 included in the second gate metal layer.

The forty-third contact hole CH43 may electrically connect the first initialization voltage connection electrode VIL1CE included in the connection metal layer and the first initialization voltage line VIL1 included in the second gate metal layer.

The forty-fourth contact hole CH44 may electrically connect the first capacitor C1 connection electrode included in the connection metal layer and the first electrode C1E1 of the first capacitor (or the first electrode C2E1 of the second capacitor) included in the second gate metal layer.

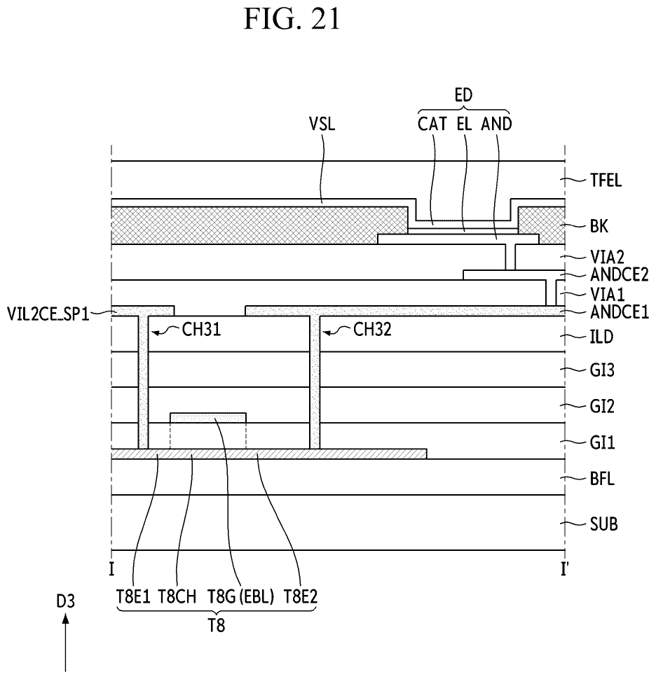

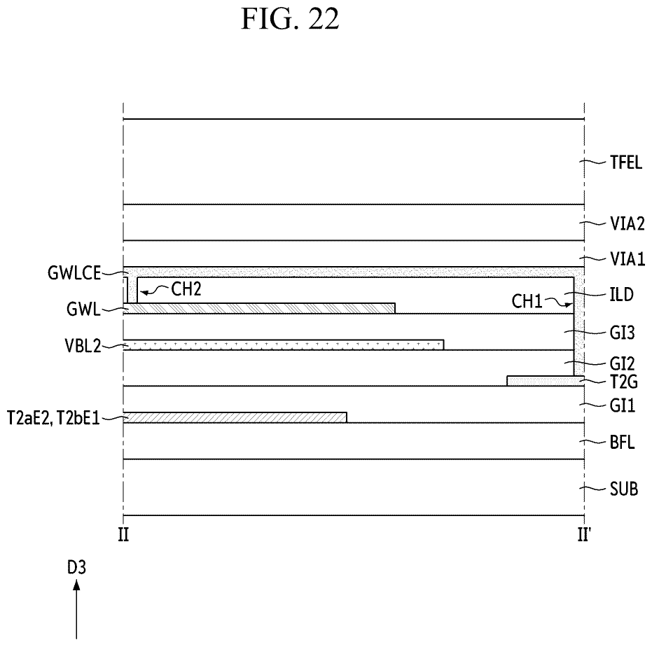

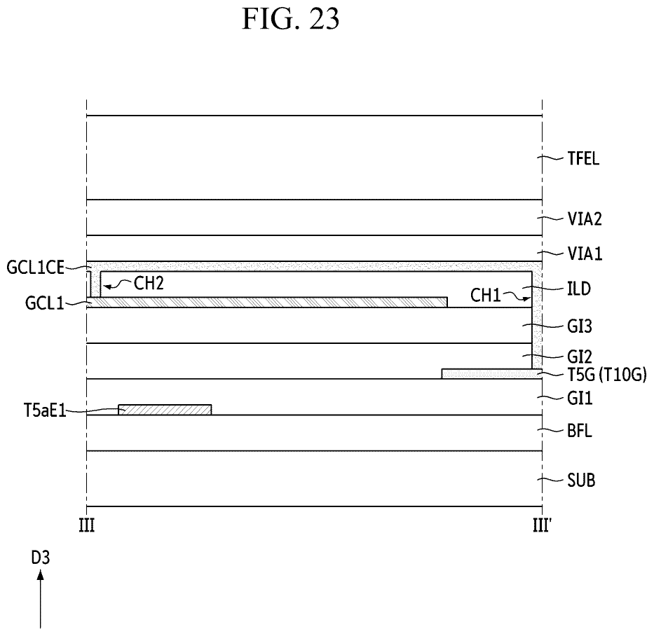

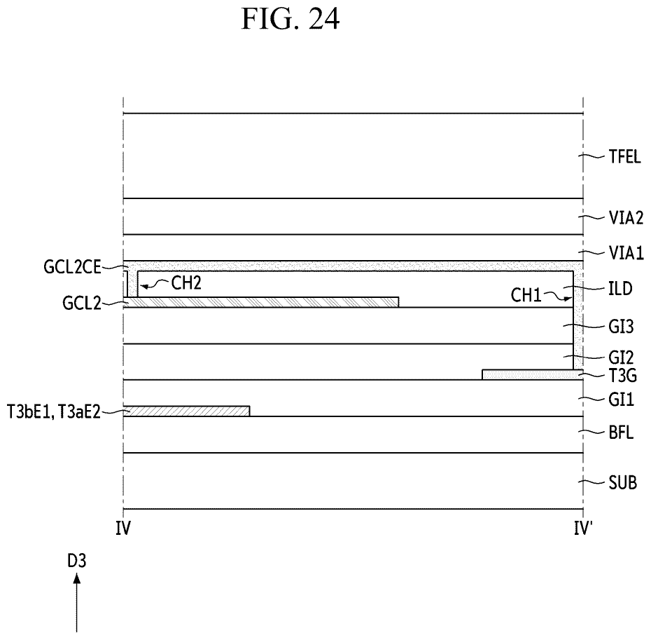

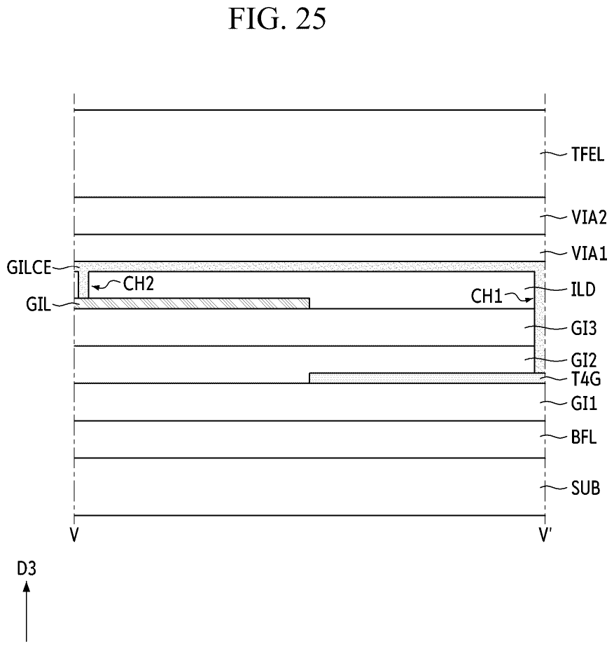

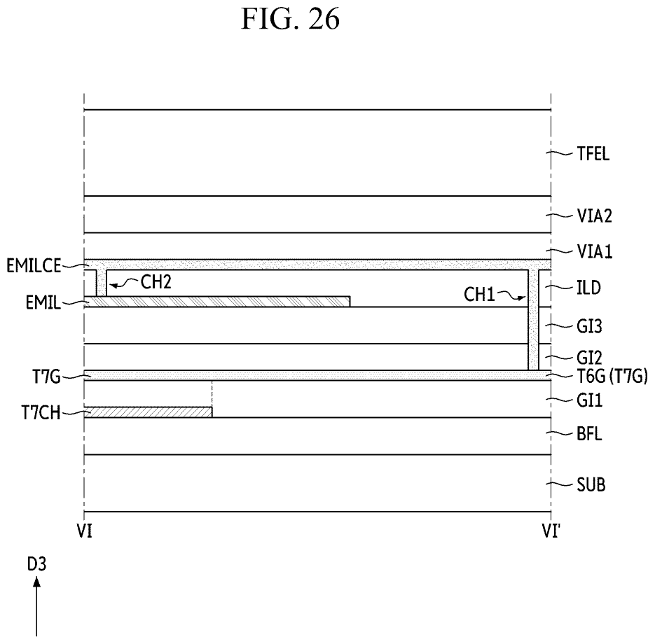

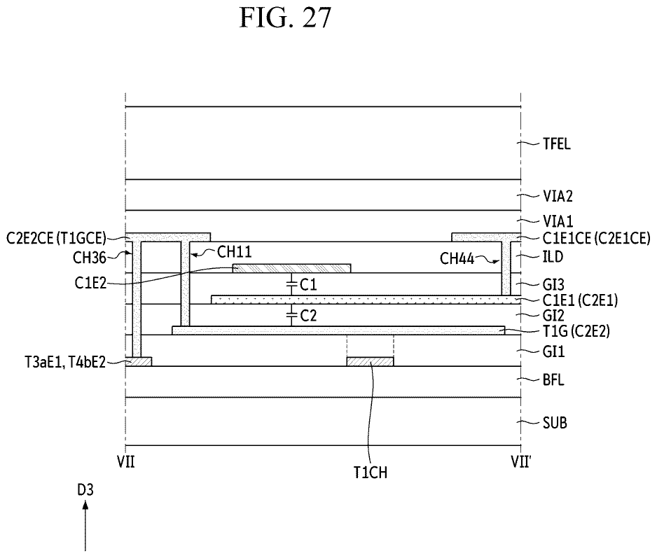

FIG. 21 is a cross-sectional view of a section taken along line I-I′ of FIGS. 15 to 20. FIG. 22 is a cross-sectional view of a section taken along line II-II′ of FIGS. 15 to 20. FIG. 23 is a cross-sectional view of a section taken along line III-III′ of FIGS. 15 to 20. FIG. 24 is a cross-sectional view of a section taken along line IV-IV′ of FIGS. 15 to 20. FIG. 25 is a cross-sectional view of a section taken along line V-V′ of FIGS. 15 to 20. FIG. 26 is a cross-sectional view of a section taken along line VI-VI′ of FIGS. 15 to 20. FIG. 27 is a cross-sectional view of a section taken along line VII-VII′ of FIGS. 15 to 20.

Referring to FIGS. 21 to 27, the display device may include a substrate SUB, a buffer film BFL arranged on the substrate SUB, an active layer arranged on the buffer film BFL, a first gate insulating film GI1 arranged to cover the active layer, a first gate metal layer arranged on the first gate insulating film GI1, a second gate insulating film GI2 arranged to cover the first gate metal layer, a second gate metal layer arranged on the second gate insulating film GI2, a third gate insulating film GI3 arranged to cover the second gate metal layer, a third gate metal layer arranged on the third gate insulating film GI3, an interlayer insulating film ILD arranged to cover the third gate metal layer, a connection metal layer arranged on the interlayer insulating film ILD, a first planarization film VIA1 arranged to cover the connection metal layer, a second connection metal layer arranged on the first planarization film VIA1, and a second planarization film VIA2 arranged to cover the second connection metal layer.

The substrate SUB may be made of an insulating material such as a polymer resin or glass. The substrate SUB may include a glass material. The substrate SUB may include polyimide. In this case, the substrate SUB may be a flexible substrate SUB that may be bent, folded, rolled, or the like.

The buffer film BFL may be formed as a silicon nitride layer, a silicon oxynitride layer, a silicon oxide layer, a titanium oxide layer, or an aluminum oxide layer.

The first gate insulating film GI1, the second gate insulating film GI2, the third gate insulating film GI3, and the interlayer insulating film ILD may each be formed as an inorganic film, for example, a silicon nitride layer, a silicon oxynitride layer, a silicon oxide layer, a titanium oxide layer, or an aluminum oxide layer.

The first planarization film VIA1 and the second planarization film VIA2 may each be formed as an organic film including an acryl resin, an epoxy resin, a phenolic resin, a polyamide resin, a polyimide resin, or the like.

The active layer may include a silicon semiconductor, such as polycrystalline silicon, single-crystalline silicon, low-temperature polycrystalline silicon, or amorphous silicon. Electrodes may be formed when ions or impurities are doped into the active layer. The doped active layer may be conductive.

The first gate metal layer, the second gate metal layer, the third gate metal layer, the connection metal layer, and the second connection metal layer may each be formed as a single layer or a multi-layer including any one of molybdenum (Mo), aluminum (Al), chromium (Cr), gold (Au), titanium (Ti), nickel (Ni), neodymium (Nd), and copper (Cu), or alloys thereof.

Referring to FIG. 21, the thirty-first contact hole CH31 may electrically connect the second initialization voltage connection electrode VIL2CE_SP1 connected to the first sub-pixel SP1 included in the connection metal layer and the first electrode T8E1 of the eighth transistor T8 included in the active layer. The thirty-second contact hole CH32 may electrically connect the first anode connection electrode ANDCE1 included in the connection metal layer and the second electrode T8E2 of the eighth transistor T8 included in the active layer.

The first anode connection electrode ANDCE1 may be electrically connected to the second anode connection electrode included in the second connection metal layer through the contact hole. The second anode connection electrode may be electrically connected to an anode electrode AND (or a pixel electrode) arranged on the second planarization film VIA2 covering the second connection metal layer.

A light emitting element ED including an anode electrode AND (or a pixel electrode), a light emitting layer EL, and a cathode electrode CAT may be arranged on the second planarization film VIA2. The cathode electrode CAT that is commonly formed in all of the pixels may also be referred to as a common electrode. The cathode electrode CAT may be at least a portion of the common voltage line VSL.

The anode electrode AND may be electrically connected to the second anode connection electrode through an anode contact hole formed in the second planarization film VIA2. In an embodiment, the first anode connection electrode ANDCE1 and the second anode connection electrode may be configured as one anode connection electrode, in which case the first planarization film VIA1 and the second planarization film VIA2 may also be configured as one planarization film.

In a top emission structure in which light is emitted toward in a direction of the cathode electrode CAT based on the light emitting layer EL, the anode electrode AND may be formed of a metal material having high reflectivity, such as a stacked structure (Ti/Al/Ti) of aluminum and titanium, a stacked structure (ITO/Al/ITO) of aluminum and indium tin oxide (ITO), an APC alloy, and a stacked structure (ITO/APC/ITO) of an APC alloy and ITO. The APC alloy is an alloy of silver, palladium, and copper.

A bank BK may be formed to partition the anode electrode AND on the second planarization film VIA2 to define the light emitting area. The light emitting area refers to an area in which the anode electrode AND, the light emitting layer EL, and the cathode electrode CAT are stacked (e.g., sequentially stacked) stacked and holes from the anode electrode AND and electrons from the cathode electrode CAT are bonded to each other in the light emitting layer EL to emit light. The bank BK may be formed to cover an edge of the anode electrode AND. The bank BK may be formed as an organic film including an acrylic resin, an epoxy resin, a phenolic resin, a polyamide resin, or a polyimide resin.

The light emitting layer EL may be formed on the anode electrode AND. The light emitting layer EL may include an organic material to emit light of a color. For example, the light emitting layer EL includes a hole transporting layer, an organic material layer, and an electron transporting layer.

The cathode electrode CAT may be arranged on the light emitting layer EL. The cathode electrode CAT may be formed to cover the light emitting layer EL. The cathode electrode CAT may be a common layer commonly formed in all light emitting areas including the illustrated light emitting area. A capping layer may be formed on the cathode electrode CAT.

In the top emission structure, the cathode electrode CAT may include transparent conductive oxide (TCO) such as indium tin oxide (ITO) or indium zinc oxide (IZO) capable of transmitting light, or a semi-transmissive conductive material such as magnesium (Mg), silver (Ag), or an alloy of magnesium (Mg) and silver (Ag). When the cathode electrode CAT includes the semi-transmissive conductive material, light emitting efficiency may be increased by a micro cavity.

An encapsulation layer TFEL may be arranged on the cathode electrode CAT. The encapsulation layer TFEL may include at least one inorganic film to prevent oxygen or moisture from permeating into the light emitting element ED. In some embodiments, the encapsulation layer TFEL may include at least one organic film to protect the light emitting element ED from foreign materials such as dust. For example, the encapsulation layer TFEL may include a plurality of inorganic films and a single organic film, but the embodiments of the present specification are not limited thereto. The inorganic film may be formed as a multi-film in which one or more inorganic films of a silicon nitride layer, a silicon oxynitride layer, a silicon oxide layer, a titanium oxide layer, and an aluminum oxide layer are alternately stacked. The organic film may include an acryl resin, an epoxy resin, a phenolic resin, a polyamide resin, a polyimide resin, or the like.

Instead of the encapsulation layer TFEL, a filling layer, a sealant, and an encapsulation substrate SUB may be arranged. In this case, the encapsulation substrate SUB may be an insulating substrate SUB including an insulating material such as glass or plastic. The filling layer may be, but is not limited to, a layer of air in a vacuum state. The sealant may be arranged in the non-display area of the display panel while surrounding the display area.

In the display device according to the embodiments of the present specification, the lines for applying the signal or voltage supplied to the gate electrodes of some transistors T2, T3, T4, T5, T6, T7, and T10 described above may be included in the third gate metal layer, and each signal or voltage may be supplied to the gate electrode via the connection metal layer.

The line for applying the signal or voltage to the gate electrodes of some transistors is arranged to intersect the data line that is arranged to extend in the second direction in the display device, as the scan line or gate line. For example, the line for applying the signal or voltage to the gate electrodes of some transistors is arranged to extend in the first direction intersecting the second direction.

The display device according to an embodiment may reduce a use of the connection metal layer by utilizing the third gate metal layer arranged to extend in the first direction. As the use of the connection metal layer is reduced, an additional design area for the connection metal layer among the lines included in the pixel circuit may be made available.

Referring to FIG. 22, the display device according to an embodiment may include the first gate line GWL and the first gate connection electrode GWLCE connected through the second contact hole CH2 formed in the interlayer insulating film ILD. In some embodiments, the first gate connection electrode GWLCE may be connected to the gate electrode T2G of the second transistor T2 through the first contact hole CH1 formed in the second gate insulating film GI2, the third gate insulating film GI3, and the interlayer insulating film ILD.

Referring to FIG. 23, the display device according to an embodiment may include the second gate line GCL1 and the second gate connection electrode GCL1CE connected through the second contact hole CH2 formed in the interlayer insulating film ILD. In some embodiments, the second gate connection electrode GCL1CE may be connected to the gate electrode T5G of the fifth transistor T5 (or the gate electrode T10G of the tenth transistor T10) through the first contact hole CH1 formed in the second gate insulating film GI2, the third gate insulating film GI3, and the interlayer insulating film ILD.

Referring to FIG. 24, the display device according to an embodiment may include the third gate line GCL2 and the third gate connection electrode GCL2CE connected through the second contact hole CH2 formed in the interlayer insulating film ILD. In some embodiments, the third gate connection electrode GCL2CE may be connected to the gate electrode T3G of the third transistor T3 through the first contact hole CH1 formed in the second gate insulating film GI2, the third gate insulating film GI3, and the interlayer insulating film ILD.

Referring to FIG. 25, the display device according to an embodiment may include the fourth gate line GIL and the fourth gate connection electrode GILCE connected through the second contact hole CH2 formed in the interlayer insulating film ILD. In some embodiments, the fourth gate connection electrode GILCE may be connected to the gate electrode T4G of the fourth transistor T4 through the first contact hole CH1 formed in the second gate insulating film GI2, the third gate insulating film GI3, and the interlayer insulating film ILD.

Referring to FIG. 26, the display device according to an embodiment may include the emission control line EML and the emission control connection electrode EMLCE connected through the second contact hole CH2 formed in the interlayer insulating film ILD. In some embodiments, the emission control connection electrode EMLCE may be connected to the gate electrode T6G of the sixth transistor T6 (or the gate electrode T7G of the seventh transistor T7) through the first contact hole CH1 formed in the second gate insulating film GI2, the third gate insulating film GI3, and the interlayer insulating film ILD.

Referring to FIG. 27, the second capacitor connection electrode C2E2CE(T1GCE) may be electrically connected to the gate electrode T1G of the first transistor T1 through the eleventh contact hole CH11. The gate electrode T1G of the first transistor T1 may be electrically connected to the first electrode of the third transistor (or the second electrode of the fourth transistor) through the eleventh contact hole CH11 and the thirty-sixth contact hole CH36.

The first capacitor connection electrode C1E1CE (C2E1CE) may be electrically connected to the first electrode C1E1 of the first capacitor (or the first electrode C2E1 of the second capacitor) through the forty-fourth contact hole CH44. As described above, the first capacitor connection electrode C1E1CE (C2E1CE) may be electrically connected to the second electrode of the second transistor (or the second electrode of the fifth transistor) through the thirty-seventh contact hole CH37. Accordingly, the second capacitor C2 may be formed between the gate electrode T1G of the first transistor T1 and the first electrode C2E1 of the second capacitor.

Although not illustrated in the drawings, the second electrode C1E2 of the first capacitor may be electrically connected to the driving voltage line through the twenty-first contact hole CH21 and the twenty-second contact hole CH22 as described above. Therefore, the second electrode C1E2 of the first capacitor may form the first capacitor C1 with the first electrode C1E1 of the first capacitor.

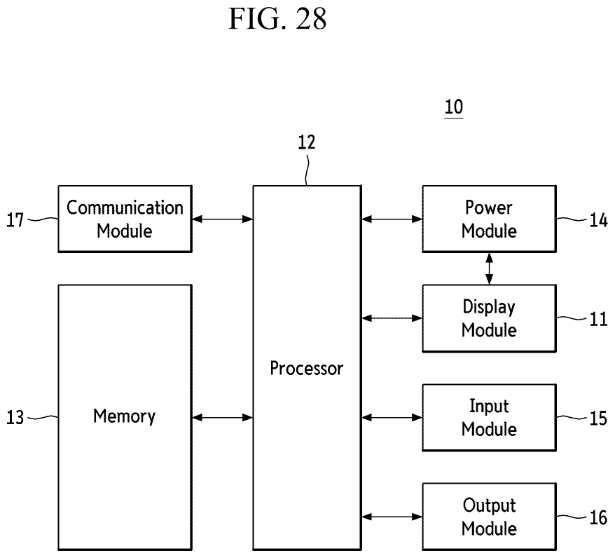

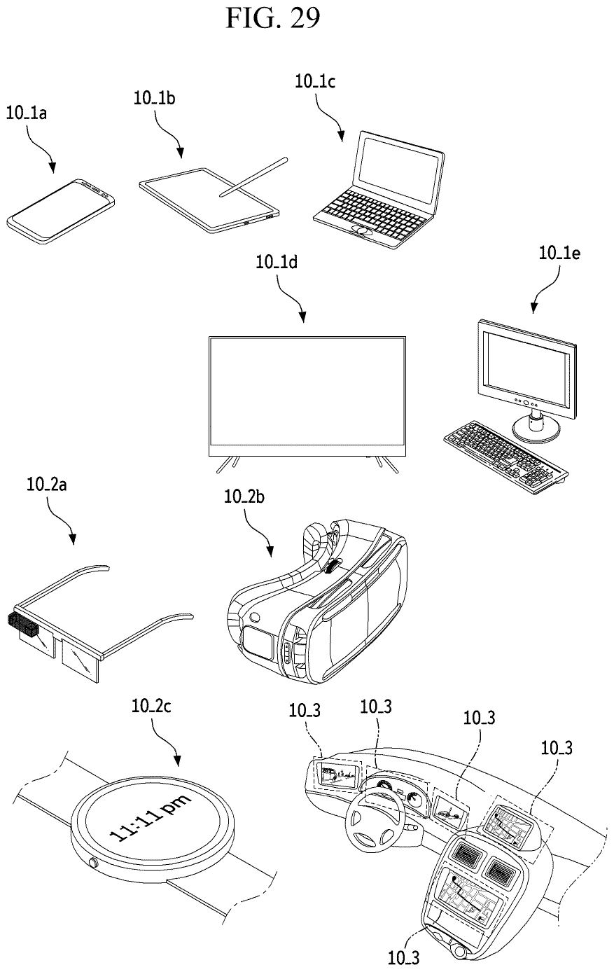

FIG. 28 is a block diagram of an electronic display device according to an embodiment of the present specification. FIG. 29 illustrates schematic diagrams of electronic devices according to various embodiments of the present specification.

Referring to FIG. 28, an electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information for an operation of the processor 12 or the display module 11 may be stored in the memory 13. Based on the processor 12 executing an application stored in the memory 13, image data signals and/or input control signals may be transmitted to the display module 11, and the display module 11 may process the provided signals and output image information via a display screen.

The power module 14 may include a power supply module such as a power adapter and/or a battery device. The power module 14 may include a power conversion module. The power conversion module may convert the power supplied by the power supply module to generate power for the operation of the electronic device 10.

At least one of the components of the electronic device 10 described above may be included in the display device according to the above-described embodiments. In some embodiments, some of the individual modules functionally included within one module may be included within the display device, while others may be provided separately from the display device. For example, the display device that includes the display module 11, the processor 12, the memory 13, and the power module 14 may be provided in the form of other devices within the electronic device other than the display device.

Referring to FIG. 29, various electronic devices to which the display device according to the embodiments of the present specification is applied may include electronic devices for displaying images, such as a smartphone 10_1a, a tablet PC 10_1b, a laptop 10_1c, a TV 10_1d, and a desk monitor 10_1e. In some embodiments, various electronic devices to which the display device according to the embodiments of the present specification is applied may include a wearable electronic device including a display module such as a smart glasses 10_2a, a head mounted display 10_2b, a smart watch 10_2c, and the like, and a vehicle electronic device 10_3 including a display module such as a Center Information Display (CID), a room mirror display, etc., arranged on a vehicle's instrument panel, center fascia, or dashboard.

Although embodiments of the disclosure have been described above with reference to the accompanying drawings, it will be understood by those having ordinary skill in the technical field to which the disclosure belongs that the disclosure may be practiced in other specific forms without altering the technical idea or essential features of the disclosure. It should therefore be understood that the embodiments described above are exemplary in all respects and are not intended to be limiting. The disclosure is also defined in the following claims and equivalents thereof.

What is claimed is:

1. A display device comprising:
a substrate;
an active layer on the substrate;
a first gate metal layer on the active layer and including a gate electrode of a second transistor and a gate electrode of a fifth transistor;
a third gate metal layer on the first gate metal layer and including a first gate line configured to receive a first gate signal and a second gate line configured to receive a second gate signal; and
a connection metal layer on the third gate metal layer and including:
a first gate connection electrode electrically connected to the first gate line; and
a second gate connection electrode electrically connected to the second gate line,
wherein the gate electrode of the second transistor is electrically connected to the first gate connection electrode, and
the gate electrode of the fifth transistor is electrically connected to the second gate connection electrode.

2. The display device of claim 1, wherein the first gate metal layer further includes a gate electrode of a third transistor,
the third gate metal layer further includes a third gate line configured to receive the second gate signal,
the connection metal layer further includes a third gate connection electrode electrically connected to the third gate line, and
the gate electrode of the third transistor is electrically connected to the third gate connection electrode.

3. The display device of claim 2, wherein the first gate metal layer further includes a gate electrode of a fourth transistor,
the third gate metal layer further includes a fourth gate line configured to receive a fourth gate signal,
the connection metal layer further includes a fourth gate connection electrode electrically connected to the fourth gate line, and
the gate electrode of the fourth transistor is electrically connected to the fourth gate connection electrode.

4. The display device of claim 3, wherein the first gate metal layer further includes a gate electrode of a sixth transistor,
the third gate metal layer further includes an emission control line configured to receive an emission control signal,
the connection metal layer further includes an emission control connection electrode electrically connected to the emission control line, and
the gate electrode of the sixth transistor is electrically connected to the emission control connection electrode.

5. The display device of claim 4, wherein the first gate metal layer further includes a fifth gate line configured to receive a fifth gate signal,
the connection metal layer further includes a data line, the first gate line, the second gate line, and the fifth gate line extending in a first direction, and
the data line extends in a second direction intersecting the first direction.

6. The display device of claim 3, further comprising a second gate metal layer between the first gate metal layer and the third gate metal layer and including a second bias voltage line configured to receive a bias voltage.

7. The display device of claim 6, wherein the active layer includes a first bias voltage line configured to receive the bias voltage.

8. The display device of claim 6, wherein the second gate metal layer further includes a first initialization voltage line configured to receive a first initialization voltage,
the connection metal layer further includes a first initialization voltage connection electrode electrically connected to the first initialization voltage line, and
a first electrode of the fourth transistor is electrically connected to the first initialization voltage connection electrode.

9. The display device of claim 1, wherein the first gate metal layer further includes a gate electrode of a tenth transistor, and
the gate electrode of the tenth transistor is electrically connected to the second gate connection electrode.

10. The display device of claim 9, wherein the gate electrode of the tenth transistor is physically connected to the gate electrode of the fifth transistor.

11. The display device of claim 4, wherein the first gate metal layer further includes a gate electrode of a seventh transistor, and
the gate electrode of the seventh transistor is electrically connected to the emission control connection electrode.

12. The display device of claim 11, wherein the gate electrode of the seventh transistor is physically connected to the gate electrode of the sixth transistor.

13. The display device of claim 6, wherein the first gate metal layer further includes a first electrode of a second capacitor, and
the second gate metal layer further includes a second electrode of the second capacitor.

14. The display device of claim 6, wherein the second gate metal layer further includes a first electrode of a first capacitor, and
the third gate metal layer further includes a second electrode of the first capacitor.

15. The display device of claim 14, wherein the connection metal layer further includes a first capacitor connection electrode electrically connected to a first electrode of the second transistor, and
the first electrode of the first capacitor is electrically connected to the first capacitor connection electrode.

16. An electronic device comprising:
a processor configured to provide an image signal;
a display module configured to receive the image signal from the processor and display an image; and
a power module configured to supply power to the display module,
wherein the display module includes:
a substrate;
an active layer on the substrate;
a first gate metal layer on the active layer and including a gate electrode of a second transistor and a gate electrode of a fifth transistor;
a third gate metal layer on the first gate metal layer and including a first gate line configured to receive a first gate signal and a second gate line configured to receive a second gate signal; and
a connection metal layer located on the third gate metal layer and including:
a first gate connection electrode electrically connected to the first gate line; and
a second gate connection electrode electrically connected to the second gate line,
wherein the gate electrode of the second transistor is electrically connected to the first gate connection electrode, and
the gate electrode of the fifth transistor is electrically connected to the second gate connection electrode.

17. The electronic device of claim 16, wherein the first gate metal layer further includes a gate electrode of a third transistor,
the third gate metal layer further includes a third gate line configured to receive a second gate signal,
the connection metal layer further includes a third gate connection electrode electrically connected to the third gate line, and
the gate electrode of the third transistor is electrically connected to the third gate connection electrode.

18. The electronic device of claim 17, wherein the first gate metal layer further includes a gate electrode of a fourth transistor,
the third gate metal layer further includes a fourth gate line configured to receive a fourth gate signal,
the connection metal layer further includes a fourth gate connection electrode electrically connected to the fourth gate line, and
the gate electrode of the fourth transistor is electrically connected to the fourth gate connection electrode.

19. The electronic device of claim 18, wherein the first gate metal layer further includes a gate electrode of a sixth transistor,
the third gate metal layer further includes an emission control line configured to receive an emission control signal,
the connection metal layer further includes an emission control connection electrode electrically connected to the emission control line, and
the gate electrode of the sixth transistor is electrically connected to the emission control connection electrode.

20. The electronic device of claim 19, wherein the first gate metal layer further includes a fifth gate line configured to receive a fifth gate signal,
the connection metal layer further includes a data line, the first gate line, the second gate line, and the fifth gate line extending in a first direction, and
the data line extends in a second direction intersecting the first direction.
